(19) United States
(12) Patent Application Publication
(10) Pub. No.: US 2015/0276990 A1
(43) Pub. Date: Oct. 1, 2015

(54) OPTICAL DEVICE, ORIGINAL PLATE, METHOD OF MANUFACTURING ORIGINAL PLATE, AND IMAGING APPARATUS

(71) Applicant: Sony Corporation, Tokyo (JP)

(72) Inventors: Makoto Sato, Tokyo (JP); Taichi Takeuchi, Kanagawa (JP); Asuka Tejima, Tokyo (JP)

(73) Assignee: Sony Corporation, Tokyo (JP)

(21) Appl. No.: 14/665,526

(22) Filed: Mar. 23, 2015

(30) Foreign Application Priority Data
Mar. 31, 2014 (JP) 2014-074950

(51) Int. Cl. G02B 1/118; G03F 7/20; G03F 7/26; G02B 1/12

(52) U.S. Cl. CPC G02B 1/118; G02B 1/12; G03F 7/20; G03F 7/26

(57) ABSTRACT

Disclosed is an optical device including a curved surface and a plurality of structures spirally provided on the curved surface at an interval of less than or equal to a wavelength of light for which reflection is to be reduced.

Each of the plurality of structures includes one of a convex portion protruding in a light-axis direction and a concave portion recessed in the light-axis direction. The curved surface has a region, in which the plurality of structures are not provided, at a center thereof.

### CROSS REFERENCE TO RELATED APPLICATIONS

This application claims the benefit of Japanese Priority Patent Application JP2014-074950 filed Mar. 31, 2014, the entire contents of which are incorporated herein by reference.

### BACKGROUND

The present technology relates to an optical device having a plurality of structures on the front surface thereof, an original plate for manufacturing the optical device, a method of manufacturing the original plate, and an imaging apparatus having the optical device.

Up until now, various technologies for reducing the reflection of light on front surfaces have been used in the technical field of optical devices. As such, a technology for forming sub-wavelength structures on the front surface of an optical device has been known (see, for example, Japanese Patent No. 4539657).

Generally, when passing through a concavo-convex shape periodically provided on the front surface of an optical device, light is diffracted with the straight advancing component thereof greatly reduced. However, if the concavo-convex shape has a pitch shorter than that of the wavelength of the passing light, the diffraction is not caused and an antireflection effect may be satisfactorily obtained.

### SUMMARY

It is desirable to provide an optical device having excellent antireflection characteristics on the curved surface thereof, an original plate for manufacturing the optical device, a method of manufacturing the original plate, and an imaging apparatus having the optical device.

According to an embodiment of the present technology, there is provided an optical device including a curved surface and a plurality of structures spirally provided on the curved surface at an interval of less than or equal to a wavelength of light for which reflection is to be reduced.

Each of the plurality of structures includes one of a convex portion protruding in a light-axis direction and a concave portion recessed in the light-axis direction. The curved surface has a region, in which the plurality of structures are not provided, at a center thereof.

According to another embodiment of the present technology, there is provided an original plate including a curved surface and a plurality of structures spirally provided on the curved surface at an interval of less than or equal to a wavelength of light for which reflection is to be reduced. Each of the plurality of structures includes one of a convex portion protruding in a central-axis direction of the curved surface and a concave portion recessed in the central-axis direction thereof. The curved surface has a region, in which the plurality of structures are not provided, at a center thereof.

According to still another embodiment of the present technology, there is provided an imaging apparatus including an optical device having a curved surface and a plurality of structures spirally provided on the curved surface at an interval of less than or equal to a wavelength of light for which reflection is to be reduced. Each of the plurality of structures includes one of a convex portion protruding in a light-axis direction of the optical device and a concave portion recessed in the light-axis direction thereof. The curved surface has a region, in which the plurality of structures are not provided, at a center thereof.

According to yet another embodiment of the present technology, there is provided a method of manufacturing an original plate including: perpendicularly applying light onto a curved surface of the original plate to form spiral exposure portions on a resist provided on the curved surface of the original plate at an interval of less than or equal to a wavelength of light for which reflection is to be reduced; developing a resist layer having the plurality of exposure portions to form a resist pattern; and etching the original plate in a central-axis direction of the curved surface using the resist pattern as a mask to form a plurality of structures on the curved surface.

As described above, it is possible to provide an optical device having excellent antireflection characteristics on the curved surface thereof according to the present technology.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1A is a schematic cross-sectional view showing an example of the configuration of an optical device according to a first embodiment of the present technology;

FIG. 1B is a schematic plane view showing an example of the arrangement of structures;

FIG. 2A is a plane view showing a part of FIG. 1B in an enlarged fashion;

FIG. 2B is a cross-sectional view taken along the line A-A in FIG. 2A;

FIG. 3A is a schematic cross-sectional view showing an example of the configuration of an original plate according to the first embodiment of the present technology;

FIG. 3B is a cross-sectional view showing a part of FIG. 3A in an enlarged fashion;

FIG. 4 is a schematic view showing an example of the configuration of an exposure apparatus used to manufacture the original plate;

FIG. 5 is a schematic view showing an example of the operation of the exposure apparatus shown in FIG. 4;

FIG. 6 is a graph showing an example of the cross-sectional shape of the aspherical surface of the original plate;

FIG. 7A is an example of a table showing the coordinate positions of the aspherical surface shown in FIG. 6 and the coordinate positions and the slant angles of a laser optical system;

FIG. 7B is a view showing the cross-sectional shape of the aspherical surface and the tracks of the laser optical system drawn based on the information shown in FIG. 7A;

FIGS. 8A to 8E are process views for describing an example of a method of manufacturing the original plate according to the first embodiment of the present technology;

FIG. 9A is an enlarged cross-sectional view of a plurality of positions extracted from the original plate in an exposure process shown in FIG. 8C;

FIG. 9B is an enlarged cross-sectional view of a plurality of positions extracted from the original plate in a development process shown in FIG. 8D;

FIG. 9C is an enlarged cross-sectional view of a plurality of positions extracted from the original plate in an etching process shown in FIG. 8E;

FIGS. 10A to 10C are process views for describing an example of a method of manufacturing the optical device according to the first embodiment of the present technology;

FIG. 11A is a schematic cross-sectional view showing a first example of the configuration of an optical device according to a modified example of the first embodiment of the present technology;

FIG. 11B is a schematic cross-sectional view showing a second example of the configuration of the optical device according to the modified example of the first embodiment of the present technology;

FIG. 12A is a schematic cross-sectional view showing a third example of the configuration of the optical device according to the modified example of the first embodiment of the present technology;

FIG. 12B is a cross-sectional view showing a part of FIG. 12A in an enlarged fashion;

FIG. 13 is a schematic view showing an example of the configuration of an exposure apparatus according to the modified example of the first embodiment of the present technology;

FIGS. 14A to 14E are process views for describing an example of a method of manufacturing an original plate according to a second embodiment of the present technology;

FIGS. 15A to 15C are process views for describing an example of a method of manufacturing a first duplicate original plate according to the second embodiment of the present technology;

FIGS. 15D to 15F are process views for describing an example of a method of manufacturing a second duplicate original plate according to the second embodiment of the present technology;

FIG. 16A is a process view for describing an example of the method of manufacturing the second duplicate original plate according to the second embodiment of the present technology;

FIGS. 16B to 16D are process views for describing an example of a method of manufacturing an optical device according to the second embodiment of the present technology;

FIG. 17 is a schematic cross-sectional view showing an example of the configuration of an injection molding apparatus used in a method of manufacturing an optical device according to a third embodiment of the present technology;

FIGS. 18A to 18D are process views for describing an example of a method of manufacturing an optical device according to a fourth embodiment of the present technology;

FIGS. 19A to 19D are process views for describing the example of the method of manufacturing the optical device according to the fourth embodiment of the present technology;

FIG. 20 is a graph showing an example of controlling a molding temperature and a pressure force in the method of manufacturing the optical device according to the fourth embodiment of the present technology;

FIG. 21 is a cross-sectional view showing an example of the configuration of an imaging device package according to a fifth embodiment of the present technology;

FIG. 22 is a cross-sectional view showing an example of the configuration of a camera module according to a sixth embodiment of the present technology;

FIG. 23 is a schematic view showing an example of the configuration of an imaging apparatus according to a seventh embodiment of the present technology;

FIG. 24 is a schematic view showing an example of the configuration of an imaging apparatus according to an eighth embodiment of the present technology;

FIG. 25A is a perspective view showing an example of the appearance of the front-surface side of a mobile phone according to a ninth embodiment of the present technology;

FIG. 25B is a perspective view showing an example of the appearance of the back-surface side of the mobile phone according to the ninth embodiment of the present technology; and

FIG. 26 is a graph showing the reflection spectrums of the lens of Example 1 and the lens of Comparative Example 1.

### DETAILED DESCRIPTION OF EMBODIMENTS

An optical device is desirably a lens such as a concave lens having a concave curved surface and a convex lens having a convex curved surface. As the convex lens, a biconvex lens, a plano-convex lens, a convex meniscus lens, or the like is desirable. As the concave lens, a bioconcave lens, a plano-concave lens, a concave meniscus lens, or the like is desirable.

The optical device desirably has an incident surface on which light is incident and an emission surface from which the light is emitted, and a plurality of structures are desirably provided on at least one of the surfaces and more desirably provided on both the surfaces.

Examples of the optical device include, but not limited to, a lens, a film, a glass plate (such as a glass plate for an imaging device package), a polymeric resin plate, a filter, a semi-transmission mirror, a dimmer device, a prism, a polarization device, and a front-surface plate for display.

The optical device is desirably applied to an optical system, an imaging apparatus, an imaging device package, an imaging module, an optical appliance, an electronic apparatus, or the like. Examples of the imaging apparatus include, but not limited to, a digital camera and a digital video camera. Examples of the optical appliance include, but not limited to, a telescope, a microscope, an exposure apparatus, a measurement apparatus, an inspection apparatus, and an analysis appliance. Examples of the electronic apparatus include, but not limited to, a personal computer, a mobile phone, a tablet computer, a display apparatus, and a drive for an optical recording medium. Examples of the optical system include, but not limited to, an optical system such as the imaging apparatus, the optical appliance, and the electronic apparatus described above.

Embodiments of the present technology will be described in the following order. Note that in all the figures of the following embodiments, the same or corresponding components will be denoted by the same symbols.

### 1. First Embodiment (Optical Device, Original Plate, and Examples of Methods of Manufacturing Optical Device and Original Plate)

### 1.1 Configuration of Optical Device

### 1.2 Configuration of Original Plate

### 1.3 Configuration of Exposure Apparatus

### 1.4 Method of Manufacturing Original Plate

### 1.5 Method of Manufacturing Optical Device

### 1.6 Effects

### 1.7 Modified Examples

### 2 Second Embodiment (Examples of Methods of Manufacturing Optical Device, Original Plate, and Duplicate Original Plate)

### 3 Third Embodiment (Example of Method of Manufacturing Optical Device)

### 4 Fourth Embodiment (Example of Method of Manufacturing Optical Device)

### 5 Fifth Embodiment (Example of Applying Optical Device to Imaging Device Package)

### 6 Sixth Embodiment (Example of Applying Optical Device to Camera Module)

### 7 Seventh Embodiment (Example of Applying Optical Device to Digital Camera)

### 8 Eighth Embodiment (Example of Applying Optical Device to Digital Video Camera)

### 9 Ninth Embodiment (Example of Applying Optical Device to Mobile Phone)

### 1. First Embodiment

### 1.1 Configuration of Optical Device

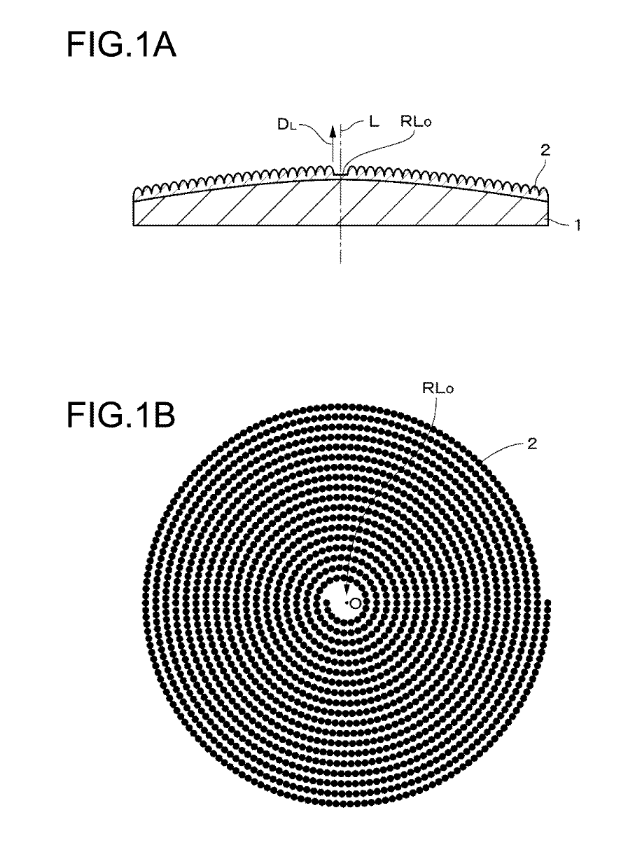

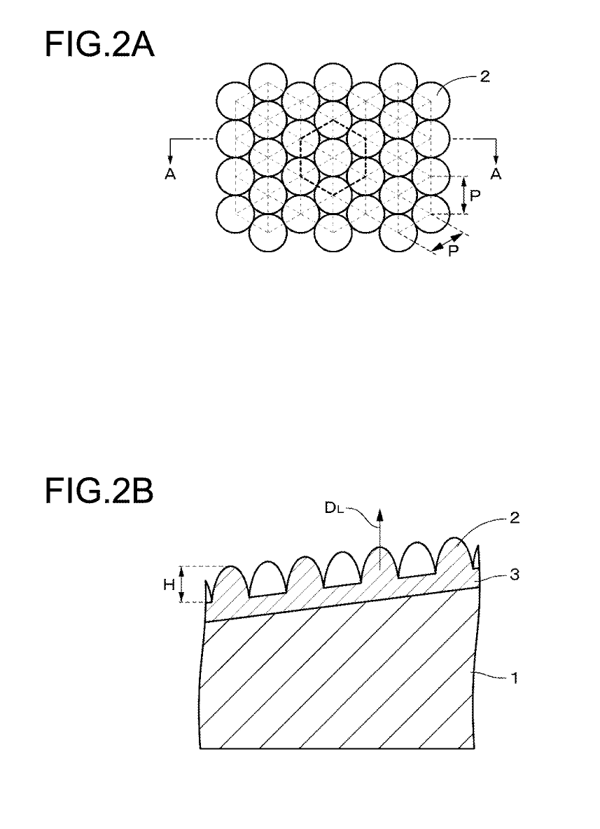

Hereinafter, a description will be given, with reference to FIGS. 1A and 1B and FIGS. 2A and 2B, of an example of the configuration of an optical device according to a first embodiment of the present technology. As shown in FIG. 1A, the optical device is a so-called plano-convex lens and has a device main body 1 and a plurality of structures 2 provided on the front surface of the device main body 1.

The device main body 1 and the plurality of structures 2 are separately or integrally molded. When the device main body 1 and the plurality of structures 2 are separately molded, the optical device may further have, if necessary, an intermediate layer 3 between the device main body 1 and the plurality of structures 2 as shown in FIG. 2B. The intermediate layer 3 is a layer integrally molded with the structures 2 on the bottom-surface side of the structures 2 and made of the same material as that of the structures 2.

As shown in FIG. 1A, the optical device has a light axis L. The light axis L is a straight line passing through the center and the focal point of the optical device. When the optical device has a rotationally-symmetric shape, the light axis L generally corresponds to the rotationally-symmetric axis of the optical device.

Hereinafter, the device main body 1 and the plurality of structures 2 of the optical device will be described sequentially.

(Device Main Body)

As shown in FIG. 1A, one surface of the device main body 1 is a convex curved surface, and the other surface thereof opposing the convex curved surface is a plane surface. The plurality of structures 2 are provided on the curved surface. With the plurality of structures 2, the curved surface is allowed to have an antireflection function. The curved surface has, for example, a shape symmetrical with respect to the light axis L. The center of the curved surface is positioned at, for example, the apex of the curved surface. Here, a description will be given of an example in which only the curved surface has the plurality of structures 2. However, both the curved surface and the plane surface or only the plane surface may have the plurality of structures 2. The curved surface may be any of a spherical surface and an aspherical surface. Examples of the aspherical surface include, but not limited to, a hyperboloidal surface, a paraboloidal surface, an ellipsoidal surface, and a free-form surface.

The curved surface is formed, for example, when a curved line in a YZ plane represented by the following formula (1) is rotated about a Z-axis.

$$Z = \frac{{Y}^{2}}{R \{ 1 + \sqrt{1 - \frac{( K + 1 ) {Y}^{2}}{{R}^{2}}} \}} + {AY}^{4} + {BY}^{6} + {CY}^{8} + {DY}^{10} \qquad ( Formula 1 )$$

(where 1/R represents a center curvature, K represents a conic constant, and A, B, C, and D represent prescribed constants.)

Note that the relationships between the conic constant K and the types of the curved surface are shown below.

K<−1: hyperboloidal surface

K=−1: paraboloidal surface

−1<K<0: ellipsoidal surface (ellipsoidal surface about long axis)

K=0: spherical surface

K>0: ellipsoidal surface (ellipsoidal surface about short axis)

The device main body 1 has transparency. As a material of the device main body 1, any of an organic material and an inorganic material may be used so long as it has transparency. Examples of the inorganic material include quartz, sapphire, and glass. As the organic material, a common polymeric material in, for example, the technical field of an optical device may be used. Specifically, examples of the common polymeric material include a thermoplastic resin such as an acrylic resin (PMMA), a polycarbonate resin (PC), and a cycloolefin polymer resin (COP).

When an organic material is used as the material of the device main body 1, an undercoating layer may be provided as font-surface treatment in order to improve front-surface energy, coating performance, slipping performance, flatness, or the like on the front surface of the device main body 1. Examples of the material of the undercoating layer include an organoalkoxymetal compound, polyester, acrylic-modified polyester, and polyurethane. In addition, front-surface treatment such as corona discharge and UV application treatment may be applied to the front surface of the device main body 1 in order to obtain the same effect as that of the undercoating layer.

(Structures)

As shown in FIG. 2B, the structures 2 are convex portions protruding in a light-axis direction D_{L} on the curved surface of the device main body 1. Here, the light-axis direction D_{L} represents a direction parallel to the light axis L of the optical device. Examples of the specific shape of the structures 2 include, but not limited to, a conical shape, a column shape, a needle shape, a hemisphere shape, and a polygonal shape. Examples of the needle shape include, but not limited to, a conical shape having an acute apex, a conical shape having a flat apex, and a conical shape having an apex of curvature R. Examples of the conical shape having the apex of curvature R include a quadratic surface shape such as a paraboloidal shape. In addition, the conical surface of the conical shape may be curved in a concave or convex form.

When the entirety of the curved surface of the device main body 1 is seen in the light-axis direction D_{L}, the plurality of structures 2 are spirally arranged, as shown in FIG. 1B, on the curved surface of the device main body 1 at a pitch (interval) P of less than or equal to the wavelength of light for which reflection is to be reduced. The center of the spiral corresponds to or substantially corresponds to the center O of the curved surface of the device main body 1. Note that the light axis L of the optical device passes through the center O of the curved surface of the device main body 1. The pitch P of the structures 2 may be different depending on the arrangement direction of the structures 2. Specifically, for example, the pitch P of the structures 2 in the peripheral direction of the spiral may be different from the pitch P of the structures 2 between the adjacent portions of the spiral. Here, the wavelength band of light for which reflection is to be reduced includes, for example, the wavelength band of ultraviolet light, the wavelength band of visible light, or the wavelength band of infrared light. The wavelength band of the ultraviolet light represents a wavelength band of greater than or equal to 10 nm and less than or equal to 350 nm, the wavelength band of the visible light represents a wavelength band of greater than or equal to 350 nm and less than or equal to 850 nm, and the wavelength band of the infrared light represents a wavelength band of more than 850 nm and less than or equal to 1 mm.

As shown in FIGS. 1A and 1B, the curved surface of the device main body 1 desirably has a region RL₀, in which the plurality of structures 2 are not provided, at the central portion thereof. This is because, when the optical device is applied to an optical system such as an imaging apparatus, the light axis of the optical system may be aligned with the light axis L of the optical device by the use of the region RL₀. The region RL₀ has a substantially circular shape.

The region RL₀ has desirably a diameter of greater than or equal to 0.07 nm in consideration of the resolution of next-generation laser scales. In addition, the region RL₀ has desirably a diameter of greater than or equal to 10 nm in consideration of the resolution of existing laser scales.

Moreover, the region RL₀ has desirably a diameter of greater than or equal to 50 nm in consideration of the precision limits of existing rotation apparatus systems.

The region RL₀ has desirably a diameter of less than or equal to 20 mm in consideration of the sizes of the unprocessed regions of CDs (Compact Discs) or the like. In addition, the region RL₀ has desirably a diameter of less than or equal to 1 mm in consideration of the fact that the optical device 1 is hardly used if it has an opening. Moreover, the region RL₀ has desirably a diameter of less than or equal to 0.1 mm in consideration of a size with which the region RL₀ is visually recognizable.

When a part of the curved surface of the device main body 1 is seen in the light-axis direction D_{L}, the plurality of structures 2 are regularly arranged on the curved surface of the device main body 1 as shown in FIG. 2A. As the regular arrangement of the structures 2, an arrangement with a lattice such as a tetragonal lattice, a quasi-tetragonal lattice, a hexagonal lattice, and a quasi-hexagonal lattice is desirable. Note that FIG. 2A shows an example in which the plurality of structures 2 are arranged in a hexagonal lattice shape. Here, the tetragonal lattice represents a regular tetragonal lattice. The quasi-tetragonal lattice represents a lattice obtained by twisting the tetragonal lattice. The hexagonal lattice represents a regular hexagonal lattice. The quasi-hexagonal lattice represents a lattice obtained by twisting the hexagonal lattice. The plurality of structures 2 include, for example, an energy ray curable resin such as an ultraviolet curable resin. The plurality of structures 2 may include various additives if necessary.

### 1.2 Configuration of Original Plate

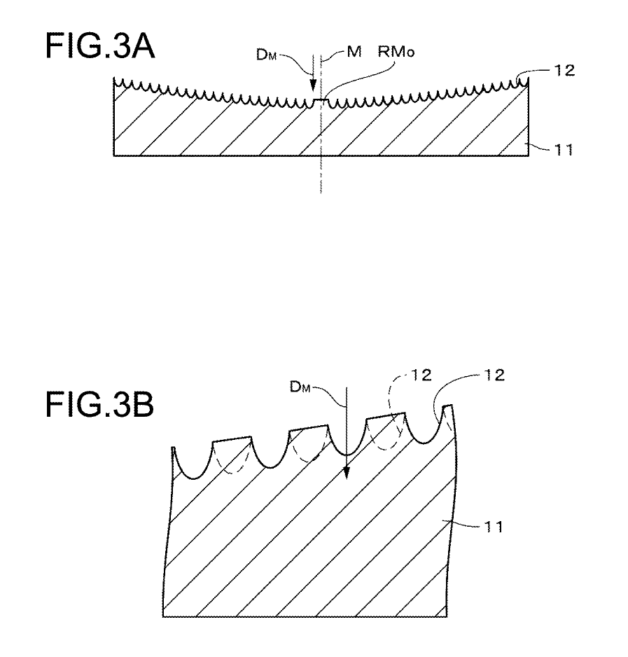

Hereinafter, a description will be given, with reference to FIGS. 3A and 3B, of an example of the configuration of an original plate 11 according to the first embodiment of the present technology. As shown in FIG. 3A, the original plate 11 has a concave curved surface, and a plurality of structures 12 are provided on the curved surface. The curved surface is a molding surface used to mold the plurality of structures 2 on the curved surface of the device main body 1. The shape of the curved surface of the original plate 11 is the same as that of the device main body 1. The original plate 11 has a central axis M. When the curved surface of the original plate 11 has a rotationally-symmetric shape, the central axis M corresponds to the rotationally-symmetric axis of the curved surface of the original plate 11. The original plate 11 may further have a protection layer on the curved surface thereof if necessary. In this case, for the purpose of maintaining the shape of the plurality of structures 2, the protection layer is provided so as to follow the shape of the plurality of structures 12.

As shown in FIG. 3B, the structures 12 are concave portions recessed in a central-axis direction D_{M} on the curved surface of the original plate 11. Here, the central-axis direction D_{M} represents a direction parallel to the central axis M of the original plate 11. When the entirety of the curved surface of the original plate 11 is seen in the central-axis direction D_{M}, the plurality of structures 12 are spirally arranged on the curved surface of the original plate 11 with a pitch (interval) P. Here, the pitch P represents a pitch of less than or equal to the wavelength of light for which reflection is to be reduced in the optical device manufactured using the original plate 12 or a duplicate of the original plate 12. The center of the spiral corresponds to or substantially corresponds to the center O of the curved surface of the original plate 11.

Note that the central axis M of the original plate 11 passes through the center of the curved surface.

The curved surface of the original plate 11 desirably has a region RM₀, in which the plurality of structures 12 are not provided, at the central portion thereof. This is because the curved surface of the device main body 1 has the region RL₀ at the central portion thereof. The arrangement and the shape of the structures 12 of the original plate 11 are the same as those of the structures 2 of the optical device described above. As a material of the original plate 11, glass, silicon, or the like may be, for example, used. However, the material of the original plate 11 is not particularly limited to such materials.

### 1.3 Configuration of Exposure Apparatus

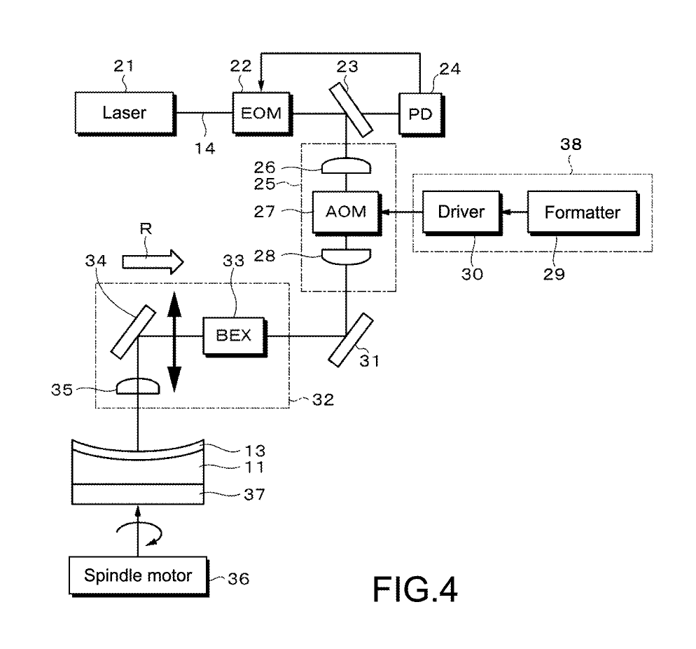

Hereinafter, a description will be given, with reference to FIG. 4, of an example of the configuration of an exposure apparatus used to manufacture the original plate 11. The exposure apparatus is based on an optical disc recording apparatus.

A laser light source 21 is a light source used to expose a resist layer 13 deposited on the front surface of the original plate 11 serving as a recording medium and oscillates recording laser light 14 having a wavelength X of, for example, 266 nm. The laser light 14 emitted from the laser light source 21 goes straight as a parallel beam and is incident on an EOM (Electro Optical Modulator) 22. The laser light 14 passing through the EOM 22 is reflected by a mirror 23 and introduced into a modulation optical system 25.

The mirror 23 is constituted by a polarization beam splitter and has the function of reflecting one polarization component while causing the other polarization component to pass through. The polarization component passing through the mirror 23 is received by a photodiode 24, and the electro optical modulator 22 is controlled based on the receiving signal to modulate the phase of the laser light 14.

In the modulation optical system 25, the laser light 14 is condensed by a condenser lens 26 on an AOM (Acousto-Optic Modulator) 27 made of glass (SiO₂) or the like. The laser light 14 is intensity-modulated and diffused by the AOM 27 and then formed into a parallel beam by a lens 28. The laser light 14 emitted from the modulation optical system 25 is reflected by a mirror 31 and horizontally and parallelly introduced onto a movement optical table 32.

The movement optical table 32 has a beam expander 33, a mirror 34, and an objective lens 35. The laser light 14 introduced onto the movement optical table 32 is formed into a desired beam shape by the beam expander 33 and then applied onto the resist layer 13 of the original plate 11 via the mirror 34 and the objective lens 35. The original plate 11 is mounted on a turn table 37 connected to a spindle motor 36. Further, the laser light 14 is moved in the height direction of the original plate 11 and intermittently applied onto the resist layer 13 while the original plate 11 is rotated, whereby an exposure process is performed on the resist layer 13. The movement of the spot of the laser light 14 on the resist layer 13 coincides with the horizontal movement of the movement optical table 32 in a direction indicated by an arrow R.

The exposure apparatus has a control mechanism 38 used to form a latent image corresponding to a two-dimensional lattice pattern such as a (quasi)-hexagonal lattice and a (quasi)-tetragonal lattice on the resist layer 13. The control mechanism 38 has a formatter 29 and a driver 30. The formatter 29 has a polarity inversion portion, and the polarity inversion portion controls timing for applying the laser light 14 onto the resist layer 13. The driver 30 controls the acousto-optic modulator 27 with the reception of an output from the polarity inversion portion.

In the exposure apparatus, a polarity inversion formatter signal and a rotation controller are synchronized with each other for every spiral cycle so as to allow the spatial linkage of a two-dimensional pattern when a signal is generated, and then the signal is intensity-modulated by acousto-optic modulator 27. For example, by patterning with an appropriate rotation number, an appropriate modulation frequency, and an appropriate feeding pitch as well as with a constant angular velocity (CAV), a lattice pattern such as a (quasi)-hexagonal lattice and a (quasi)-tetragonal lattice may be recorded on the resist layer 13.

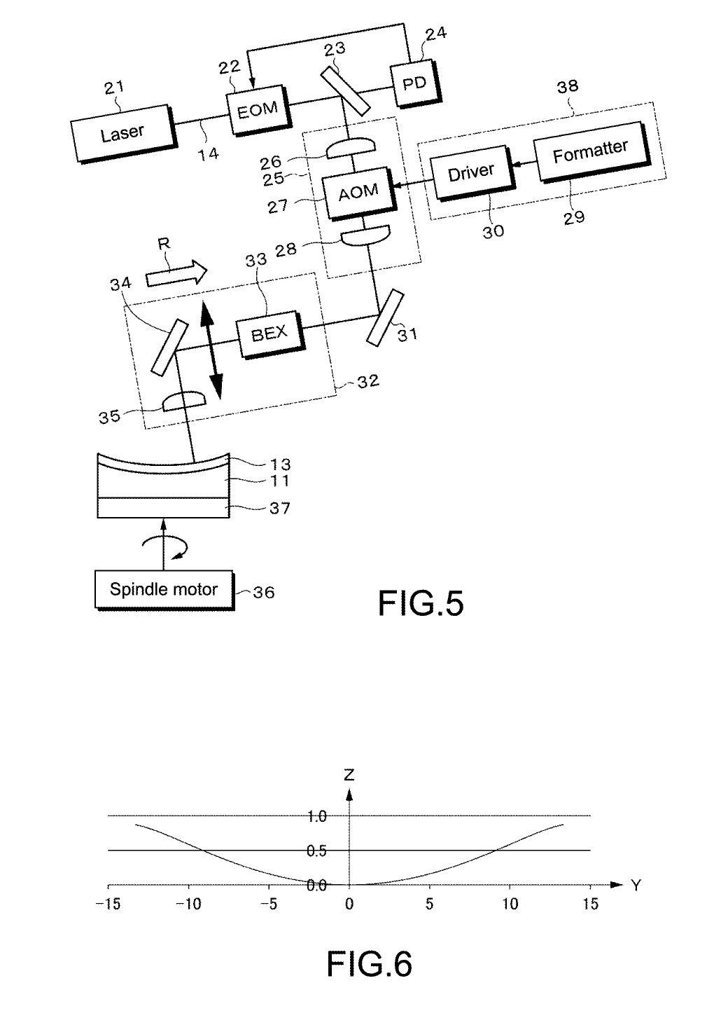

In the exposure apparatus having the configuration described above, the laser optical system is entirely tilted to allow the laser light 14 to be perpendicularly applied onto the curved surface of the original plate 11 as shown in FIG. 5. Thus, an exposure pattern may be formed on the resist layer 13 in a state in which the laser light 14 is kept perpendicularly applied onto the curved surface of the original plate 11 from the center to the periphery of the curved surface of the original plate 11.

Hereinafter, a description will be given of an example of the operation of the exposure apparatus having the configuration described above. Here, a description will be given of an example of position control by the laser optical system of the exposure apparatus when the original plate 11 having an aspheric surface represented by the following formula (2) is exposed.

$$Z = \frac{{Y}^{2}}{80 \{ 1 + \sqrt{1 - \frac{( 0.01 + 1 ) {Y}^{2}}{{80}^{2}}} \}} + 0 {Y}^{4} + {1}^{- 6} {Y}^{6} - {5}^{- 8} {Y}^{8} + {5}^{- 12} {Y}^{10} \qquad ( Formula 2 )$$

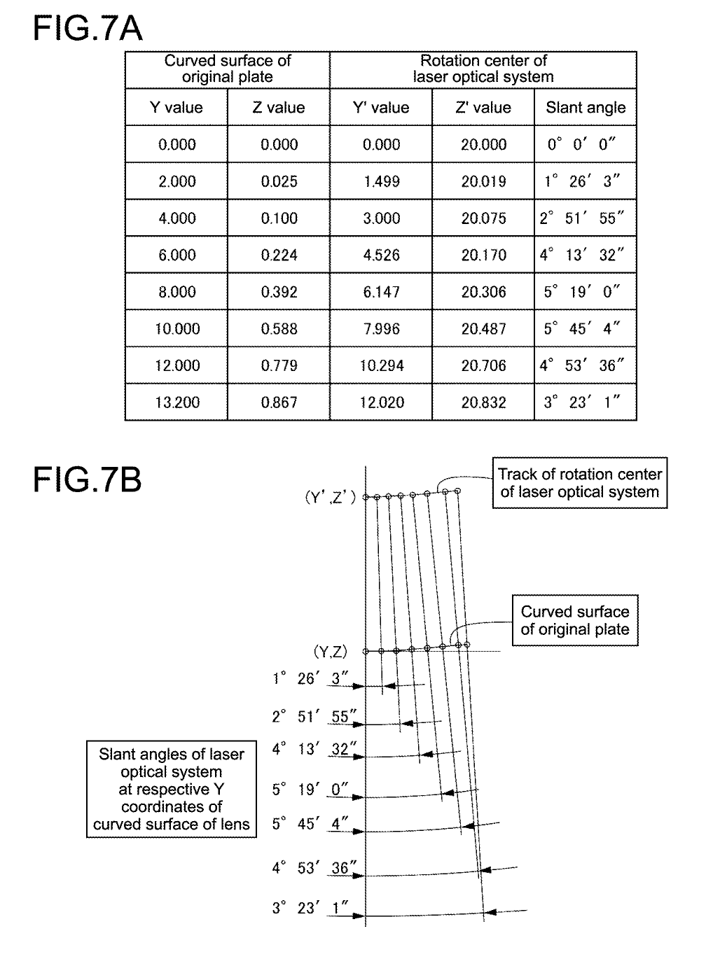

FIG. 6 shows the shape of a concave aspheric surface represented by the formula (2). FIGS. 7A and 7B show the tracks of the laser optical system when the distance between the curved surface shown in FIG. 6 and the rotation center of the laser optical system of the exposure apparatus is set at 20 mm. Note that in FIGS. 7A and 7B, the position of the curved surface of the original plate 11 is represented by (Y, Z) and the position of the rotation center of the laser optical system corresponding to the position (Y, Z) is represented by (Y′, Z′). When the original plate 11 having the aspherical surface represented by the above formula (2) is exposed, the operation of the laser optical system is controlled such that the rotation center of the laser optical system passes through coordinates shown in FIG. 7A, i.e., the tracks shown in FIG. 7B are drawn.

### 1.4 Method of Manufacturing Original Plate

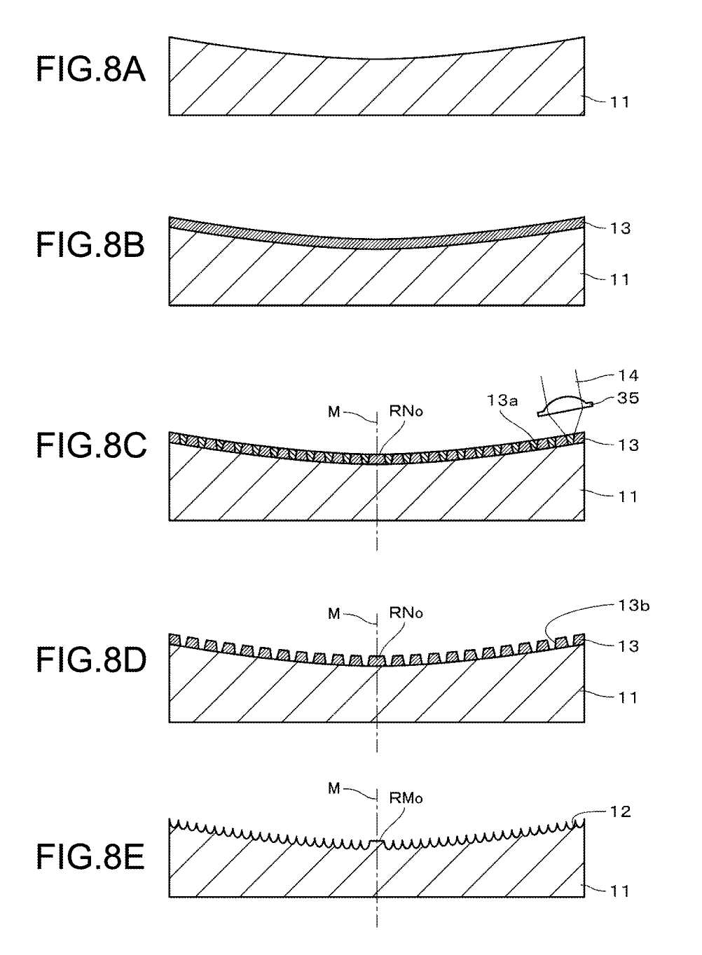

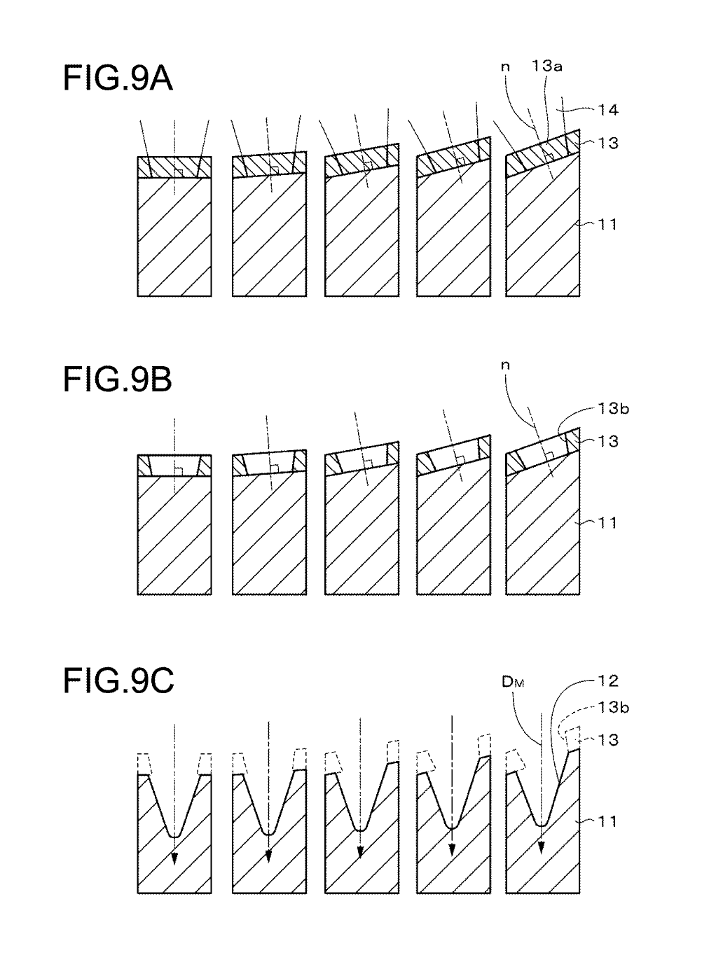

Hereinafter, a description will be given, with reference to FIGS. 8A to 8E and FIGS. 9A to 9C, of an example of a method of manufacturing the original plate according to the first embodiment of the present technology.

(Resist Deposition Process)

First, as shown in FIG. 8A, the original plate 11 having a concave curved surface is prepared. The original plate 11 is, for example, a glass original plate. Next, as shown in FIG. 8B, the resist layer 13 is evenly formed on the curved surface of the original plate 11. As a material of the resist layer 13, any of an organic resist and an inorganic resist may be, for example, used. As the organic resist, a novolac resist, a chemically-amplified resist, or the like may be, for example, used. As the inorganic resist, the incomplete oxide of transition metal or the like may be, for example, used.

(Exposure Process)

Then, as shown in FIG. 8C, the laser light (exposure beam) 14 is applied onto the resist layer 13 formed on the curved surface of the original plate 11. Specifically, the original plate 11 is mounted and rotated on the turn table 37 of the exposure apparatus shown in FIG. 4 and the laser light 14 is intermittently applied while being moved from the center to the peripheral direction of the curved surface of the original plate 11, whereby the resist layer 13 formed on the curved surface of the original plate 11 is exposed. On this occasion, as shown in FIG. 9A, the laser optical system is controlled such that the laser light 14 is kept perpendicularly incident on the curved surface of the original plate 11, i.e., the laser light 14 is kept incident so as to be parallel to a normal line n of the curved surface of the original plate 11. When the resist layer 13 includes an inorganic resist such as the incomplete oxide of transition metal, the phase of the inorganic resist is changed by the exposure.

By the exposure, a plurality of latent images 13a are formed on the resist layer 13. Specifically, the plurality of latent images 13a are spirally formed when the entirety of the curved surface of the original plate 11 is seen in the central-axis direction D_{M}. In addition, the plurality of latent images 13a are formed with a regular pattern such as a lattice pattern when a part of the curved surface of the original plate 11 is seen in an enlarged fashion in the central-axis direction D_{M}.

For example, the start position of the exposure is the central position of the curved surface of the original plate 11 and desirably a position slightly deviating from the center of the curved surface of the original plate 11. Thus, the curved surface of the original plate 11 may have a non-exposure region RN₀, in which the resist layer 13 is not exposed, at the central portion thereof. That is, in an etching process that will be described later, the curved surface of the original plate 11 may have the region RM₀, in which the plurality of structures 12 are not provided, at the central portion thereof. The latent images 13a have, for example, a substantially circular shape, a substantially elliptical shape, or the like.

(Development Process)

Next, for example, a developing solution is dropped onto the resist layer 13 while the original plate 11 is rotated, whereby the resist layer 13 is developed. Thus, as shown in FIG. 8D, a plurality of opening portions 13b are formed on the resist layer 13. More specifically, the resist layer 13 is developed in a direction perpendicular to the curved surface of the original plate 11, i.e., in the direction of the normal line n of the curved surface of the original plate 11, whereby the plurality of opening portions 13b are formed on the resist layer 13. Since portions exposed by the laser light 14 are dissolved by the developing solution at a rate faster than that of non-exposed portions when the resist layer 13 is made of a positive resist, a pattern corresponding to the latent images 13a is formed on the resist layer 13 as shown in FIG. 8D and FIG. 9B.

(Etching Process)

Then, the curved surface of the original plate 11 is etched using the pattern (resist pattern) of the resist layer 13 formed on the curved surface of the original plate 11 as a mask. On this occasion, as shown in FIG. 9C, the etching process is controlled such that the original plate 11 is etched in the central-axis direction D_{M}. Thus, as shown in FIG. 8E, the plurality of structures 12 are formed on the curved surface of the original plate 11. Note that the etching process and an ashing process may be alternately performed to control the shape of the plurality of structures 12. As the etching process, dry etching, wet etching, or the like may be, for example, used. As the dry etching, RIE (Reactive Ion Etching) may be, for example, used. Next, the resist layer 13 remaining on the curved surface of the original plate 11 is removed by the ashing process. Thus, the original plate 11 as a target is obtained.

### 1.5 Method of Manufacturing Optical Device

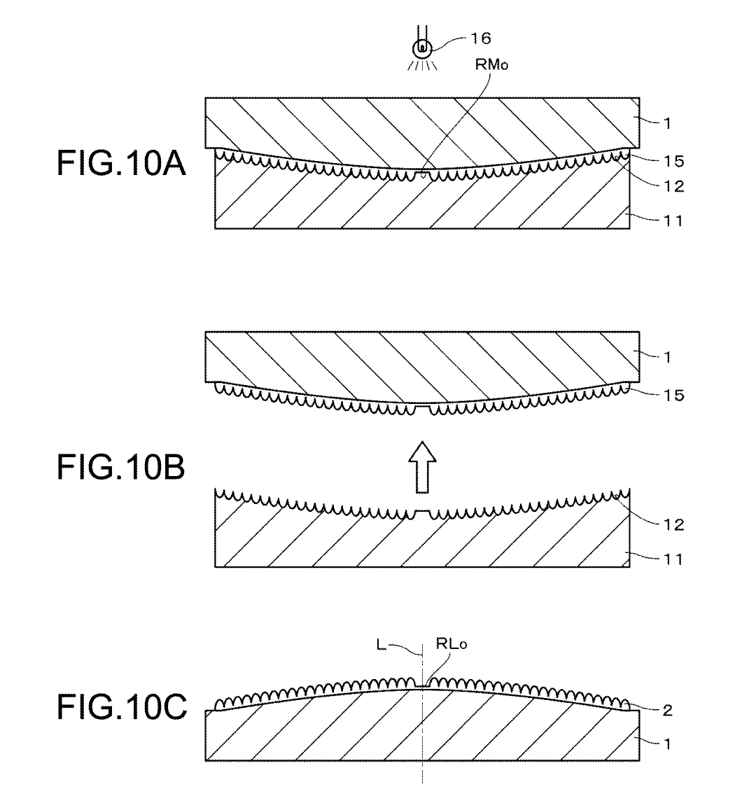

Hereinafter, a description will be given, with reference to FIGS. 10A to 10C, of an example of a method of manufacturing the optical device according to the first embodiment of the present technology.

First, front-surface treatment such as corona treatment may be applied to the convex curved surface of the device main body 1 if necessary. Next, as shown in FIG. 10A, a transfer material 15 is interposed between the convex curved surface of the device main body 1 and the concave curved surface (molding surface) of the original plate 11 and brought into intimate contact with both the curved surfaces, while an energy ray such as ultraviolet light is applied from an energy ray source 16 onto the transfer material 15. Thus, the transfer material 15 is cured.

As the energy ray source 16, a source capable of discharging an energy ray such as an electron beam, ultraviolet light, infrared light, laser light, visible light, ionizing radiation (X-ray, α-ray, β-ray, γ-ray, or the like), a microwave, and a high-frequency wave may be used. However, the energy ray source 16 is not particularly limited.

As the transfer material 15, an energy ray curable resin composition may be desirably used. As the energy ray curable resin composition, an ultraviolet curable resin composition may be desirably used. The energy ray curable resin composition may include a filler, a functional additive, or the like if necessary.

The ultraviolet curable resin composition includes, for example, acrylate and an initiator. The ultraviolet curable resin composition includes, for example, a mono-functional monomer, a bi-functional monomer, a multi-functional monomer, or the like and specifically includes a composition in which any of the following materials is singly used or the materials are mixed together.

Examples of the mono-functional monomer may include carboxylic acid types (acrylic acid), hydroxy types (2-hydroxyethyl acrylate, 2-hydroxypropyl acrylate, 4-hydroxybutyl acrylate), alkyl, alicyclic types (isobutyl acrylate, t-butyl acrylate, isooctyl acrylate, lauryl acrylate, stearyl acrylate, isobornyl acrylate, cyclohexyl acrylate), and other functional monomers (2-methoxyethyl acrylate, methoxyethylene glycol acrylate, 2-ethoxyethyl acrylate, tetrahydrofurfuryl acrylate, benzyl acrylate, ethylcarbitol acrylate, phenoxyethyl acrylate, N,N-dimethylaminoethyl acrylate, N,N-dimethylaminopropyl acrylic amid, N,N-dimethyl acrylic amid, acryloyl morpholine, N-isopropyl acrylic amid, N,N-dimethyl acrylic amid, N-vinyl pyrrolidone, 2-(perfluorooctyl)ethyl acrylate, 3-perfluorohexyl-2-hydroxypropyl acrylate, 3-perfluorooctyl-2-hydroxypropyl acrylate, 2-(perfluorodecyl)ethyl acrylate, 2-(perfluoro-3-methylbutyl)ethyl acrylate, 2,4,6-tribromophenol acrylate, 2,4,6-tribromophenol methacrylate, 2-(2,4,6-tribromophenoxyl)ethyl acrylate, and 2-ethylhexyl acrylate).

Examples of the bi-functional monomer may include tri(propylene glycol)diacrylate, trimethylol propane diallyl ether, and urethane acrylate.

Examples of the multi-functional monomer may include trimethylol propane triacrylate, dipenta erythritol penta and hexaacrylate, and ditrimethylol propane tetraacrylate.

Examples of the initiator may include 2,2-dimethoxy-1,2-diphenylethane-1-on, 1-hydroxy-cyclohexyl phenyl ketone, and 2-hydroxy-2-methyl-1-phenyl propane-1-on.

As the filler, both inorganic fine particles and organic fine particles may be used. As the inorganic fine particles, fine particles containing metal oxides may be, for example, used. As the metal oxides, one or more types selected from a group including silicon oxide (SiO₂), titanium oxide (TiO₂), zirconium oxide (ZrO₂), tin oxide (SnO₂), aluminum oxide (Al₂O₃), or the like may be, for example, used.

Examples of the functional additive may include an ultraviolet absorbent, a catalyzer, a colorant, an antistat, a lubricant, a leveling agent, a front-surface regulator, an antifoam, an antioxidant, a fire retardant, an infrared absorbent, a surfactant, a front-surface modifier, a thixotropic agent, and a plasticizer.

From the viewpoint of improving the separation of the original plate 11, it is desirable to further add an additive such as a fluorine-based additive and a silicone-based additive to the transfer material 15.

Next, as shown in FIG. 10B, the device main body 1 integrated with the cured transfer material 15 is separated from the curved surface of the original plate 11. Thus, as shown in FIG. 10C, the plurality of structures 2 are formed on the curved surface of the device main body 1. On this occasion, the intermediate layer 3 may be formed between the device main body 1 and the plurality of structures 2 if necessary. In the way described above, the optical device is obtained as desired.

### 1.6 Effects

Since the optical device according to the first embodiment has the plurality of structures 2 spirally provided on the curved surface thereof at an interval of less than or equal to the wavelength of light for which reflection is to be reduced, it is possible to provide the curved surface with excellent antireflection characteristics.

In the optical device according to the first embodiment, the curved surface of the device main body 1 has the region RL₀, in which the plurality of structures 2 are not provided, at the central portion thereof. Accordingly, when the optical device is applied to an optical system such as an imaging apparatus, it is possible to align the light axis of the optical system and the light axis L of the optical device with each other using the region RL₀.

In the method of manufacturing the original plate according to the first embodiment, the original plate 11 is rotated and the laser light 14 is intermittently applied onto the resist layer 13 while being moved from the center to the peripheral direction of the original plate 11, whereby a spiral exposure pattern is formed. Thus, it is possible to expose the resist layer 13 accurately and with a short period of time. Accordingly, it is possible to improve the productivity of the original plate 11. In addition, since the spiral exposure pattern is employed, it is possible to reduce the fluctuation of a feeding pitch in a radius direction compared with a case in which a concentric exposure pattern is employed. That is, it is possible to reduce the fluctuation of the distance between the structures 12 in the radius direction. Thus, it is possible to reduce the occurrence of diffraction light or the like.

In the method of manufacturing the original plate according to the first embodiment, it is possible to form the structures 12 such as moth-eye structures on a curved surface such as an aspherical surface. In addition, it is possible to set the position, the size, the shape, the depth, the slant-surface shape, or the like of the plurality of structures 12 with the numeric control of the irradiation time, the irradiation energy amount, and the irradiation interval of laser light for use in exposure. Accordingly, it is possible to control the reflectivity characteristics of the optical device molded using the original plate 11.

In the method of manufacturing the optical device according to the first embodiment, it is possible to provide an optical device such as an aspherical lens, a spherical lens, and an imager cover glass with antireflection characteristics through a shape transfer using the original plate 11. Accordingly, it is possible to improve the productivity of an optical device having antireflection characteristics.

### 1.7 Modified Examples

### Optical Device

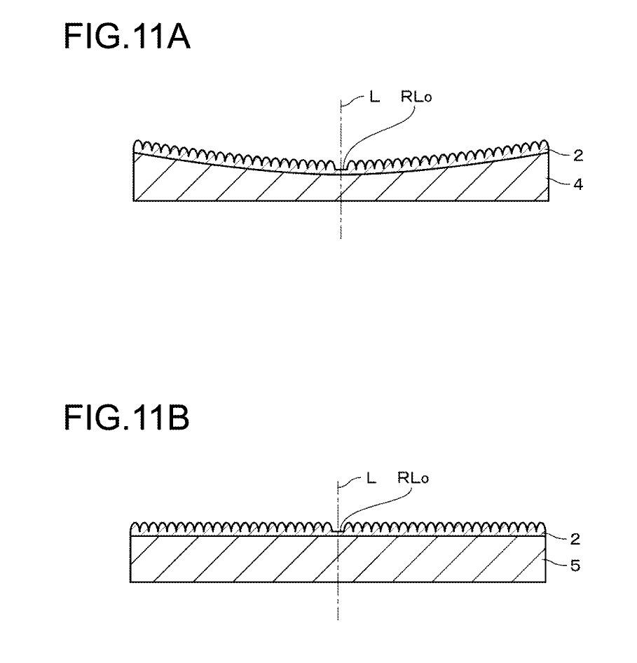

The first embodiment described above exemplifies the configuration in which the device main body 1 has the convex curved surface and the plurality of structures 2 are provided on the curved surface. However, the front surface on which the plurality of structures 2 are provided may have any shape. For example, as shown in FIG. 11A, it may be possible that an optical device is a so-called plano-concave lens, a device main body 4 has a concave curved surface, and the plurality of structures 2 are provided on the concave curved surface. The curved surface has, for example, a shape symmetric with respect to a light axis L. The center of the curved surface is positioned at, for example, the bottom portion of the curved surface. In this case as well, the curved surface desirably has the region RL₀, in which the plurality of structures 2 are not provided, at the central portion thereof. In addition, as shown in FIG. 11B, it may be possible that a device main body 5 has a plane surface and the plurality of structures 2 are provided on the plane surface. In this case as well, the plane surface desirably has the region RL₀, in which the plurality of structures 2 are not provided, at the central portion thereof.

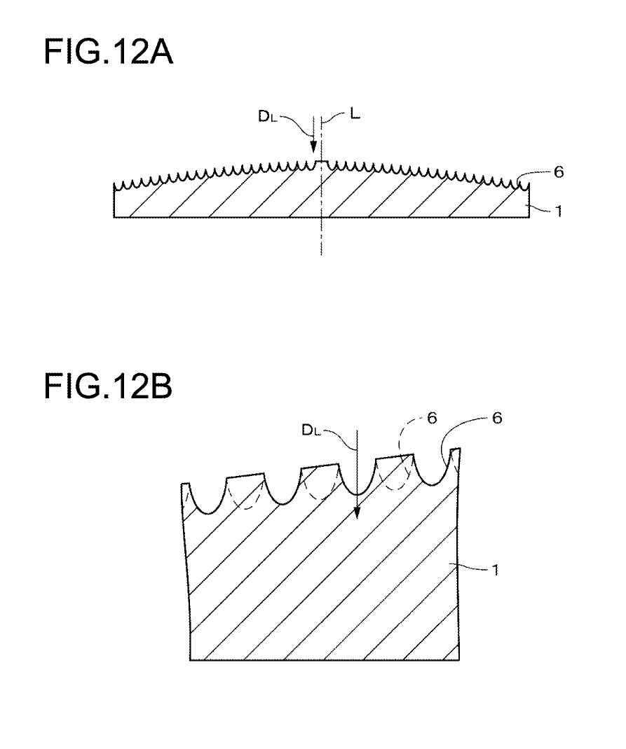

The first embodiment described above exemplifies the configuration in which the structures 2 are the convex portions protruding in the light-axis direction D_{L} on the curved surface of the device main body 1. However, the structures 2 may have any configuration. For example, as shown in FIGS. 12A and 12B, structures 6 may be concave portions recessed in the light-axis direction D_{L} on the curved surface of the device main body 1.

(Exposure Apparatus)

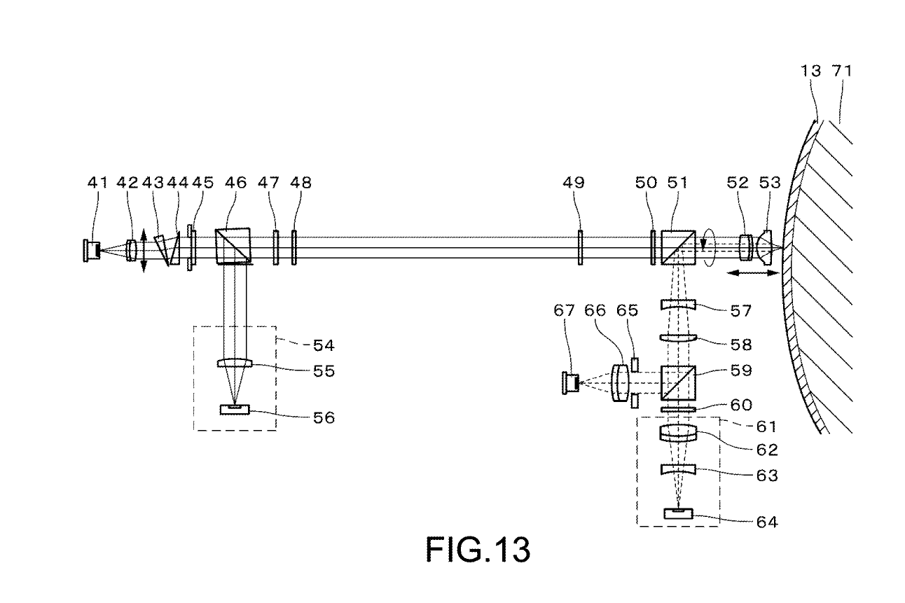

As shown in FIG. 13, an exposure apparatus according to a modified example of the first embodiment of the present technology has laser diodes 41 and 67, beam splitters 46, 51, and 59, an auto power control portion 54, and a focus control portion 61. The auto power control portion 54 has a condenser lens 55 and a photo detector 56.

The focus control portion 61 has lenses 62 and 63 and a photo detector 64.

A collimator lens 42, beam shaping prisms 43 and 44, and a ½ wavelength plate 45 are provided between the laser diode 41 and the beam splitter 46. ½ wavelength plates 47 to 49 and a ¼ wavelength plate 50 are provided between the beam splitters 46 and 51. A collimator lens 52 and a condenser lens 53 are provided between the beam splitter 51 and an original plate 71.

Lenses 57 and 58 are provided between the beam splitters 51 and 59. A noise reduction portion 61 is provided between the beam splitter 59 and the focus control portion 61. An aperture 65 and a collimator lens 66 are provided between the laser diode 67 and the beam splitter 59.

Blue laser light (having a wavelength of 405 nm) emitted from the laser diode 41 is converted from diffused light to parallel light by the collimator lens 42. Then, with the spot shape thereof shaped by the beam shaping prisms 43 and 44, the converted light is incident on the beam splitter 46 via the ½ wavelength plate 45.

The beam splitter 46 causes the blue laser light incident from the laser diode 41 to pass through while reflecting the blue laser light reflected by a resist layer 13 of the original plate 71. Thus, the light path of the blue laser light traveling to the resist layer 13 is separated from the light path of the blue laser light returning from the resist layer 13.

The blue laser light reflected by the beam splitter 46 is condensed by the condenser lens 55 and received by the photo detector 56.

The blue laser light passing through the beam splitter 46 is incident on the beam splitter 51 via the ½ wavelength plates 47 to 49 and the ¼ wavelength plate 50.

The beam splitter 51 causes the blue laser light incident from the laser diode 41 to pass through while causing the blue laser light reflected by the resist layer 13 of the original plate 71 to pass through.

The blue laser light passing through the beam splitter 51 is incident on the resist layer 13 of the original plate 71 via the collimator lens 52 and the condenser lens 53. The blue laser light reflected by the resist layer 13 is converted from diffused light to parallel light by the condenser lens 53 and incident on the beam splitter 51 via the collimator lens 52.

Red laser light (having a wavelength of 650 nm) emitted from the laser diode 67 is converted from diffused light to parallel light by the collimator lens 66 and then incident on the beam splitter 59 via the aperture 65. The beam splitter 59 reflects the red laser light incident from the laser diode 67. The reflected light is incident on the beam splitter 51 via the lenses 58 and 57.

The beam splitter 51 reflects the red laser light incident from the laser diode 67 toward the resist layer 13 of the original plate 71 while reflecting the red laser light reflected by the resist layer 13 of the original plate 71 toward the beam splitter 59.

The red laser light reflected by the beam splitter 51 is incident on the beam splitter 59 via the lenses 57 and 58. The beam splitter 59 causes the red laser light incident from the beam splitter 51 to pass through. The light passing through the beam splitter 59 is received by the photo detector 56 via the noise reduction portion 60 and the lenses 62 and 63.

In the exposure apparatus having the configuration described above, it is possible to perform exposure with the adjustment of differences from the tracks shown in FIGS. 7A and 7B using an auto focus mechanism in consideration of an error in manufacturing a lens relative to an aspherical surface represented by the above formula (1) and an error in the thickness of the deposited resist layer 13. Red laser light for auto focus is emitted from an optical system, and an amount of the light reflected by the front surface of the resist layer 13 is detected, whereby it is possible to control the application of the laser light onto the resist layer 13 with an accuracy of, for example, less than or equal to 10 nm.

### 2. Second Embodiment

A second embodiment will describe a method of manufacturing an optical device. Specifically, a first duplicate original plate (hereinafter referred to as a “master original plate”) is manufactured based on an original plate, and then a second duplicate original plate (hereinafter referred to as a “mother original plate”) is manufactured based on the master original plate. The optical device is manufactured using the mother original plate. In the following example, an optical device having a concave curved surface shown in FIG. 11A is manufactured as such.

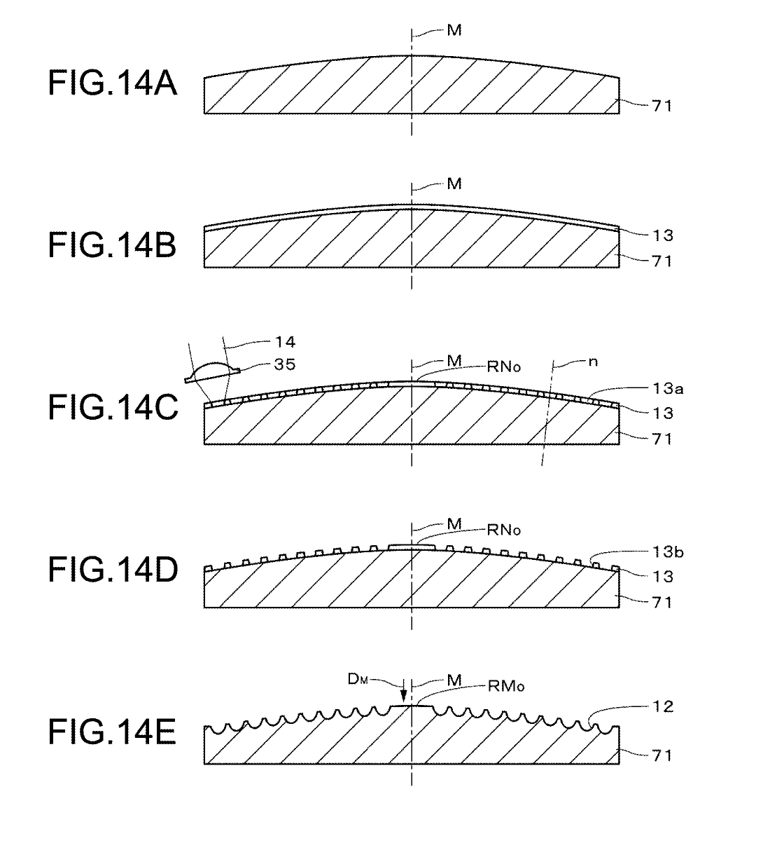

Hereinafter, a description will be given, with reference to FIGS. 14A to 14E to FIGS. 16A to 16D, of examples of methods of manufacturing an original plate, a master original plate, a mother original plate, and an optical device according to the second embodiment of the present technology.

(Method of Manufacturing Original Plate)

First, as shown in FIG. 14A, an original plate 71 having a convex curved surface is prepared. Next, as shown in FIG. 14B, a resist layer 13 is evenly formed on the curved surface of the original plate 71.

Then, as shown in FIG. 14C, laser light (exposure beam) 14 is applied onto the resist layer 13 formed on the curved surface of the original plate 71. Specifically, the original plate 71 is mounted and rotated on the turn table 37 of the exposure apparatus shown in FIG. 4 and the laser light 14 is intermittently applied while being moved from the center to the peripheral direction of the curved surface of the original plate 71, whereby the resist layer 13 formed on the curved surface of the original plate 71 is exposed. On this occasion, the laser optical system is controlled such that the laser light 14 is kept perpendicularly incident on the curved surface of the original plate 71, i.e., the laser light 14 is kept incident so as to be parallel to a normal line n of the curved surface of the original plate 71. By the exposure, a plurality of latent images 13a are formed on the resist layer 13. In this case as well, the curved surface of the original plate 71 desirably has a non-exposure region RN₀, in which the resist layer 13 is not exposed, at the central portion thereof.

Next, for example, a developing solution is dropped onto the resist layer 13 while the original plate 71 is rotated, whereby the resist layer 13 is developed. Thus, as shown in FIG. 14D, a plurality of opening portions 13b are formed on the resist layer 13.

Then, the curved surface of the original plate 71 is etched using the pattern (resist pattern) of the resist layer 13 formed on the curved surface of the original plate 11 as a mask. On this occasion, the etching process is controlled such that the original plate 71 is etched in a central-axis direction D_{M}. Thus, as shown in FIG. 14E, a plurality of concave structures 12 are formed on the curved surface of the original plate 71. In this case, the curved surface of the original plate 71 desirably has a region RM₀, in which the plurality of structures 12 are not provided, at the central portion thereof.

(Method of Manufacturing Master Original Plate)

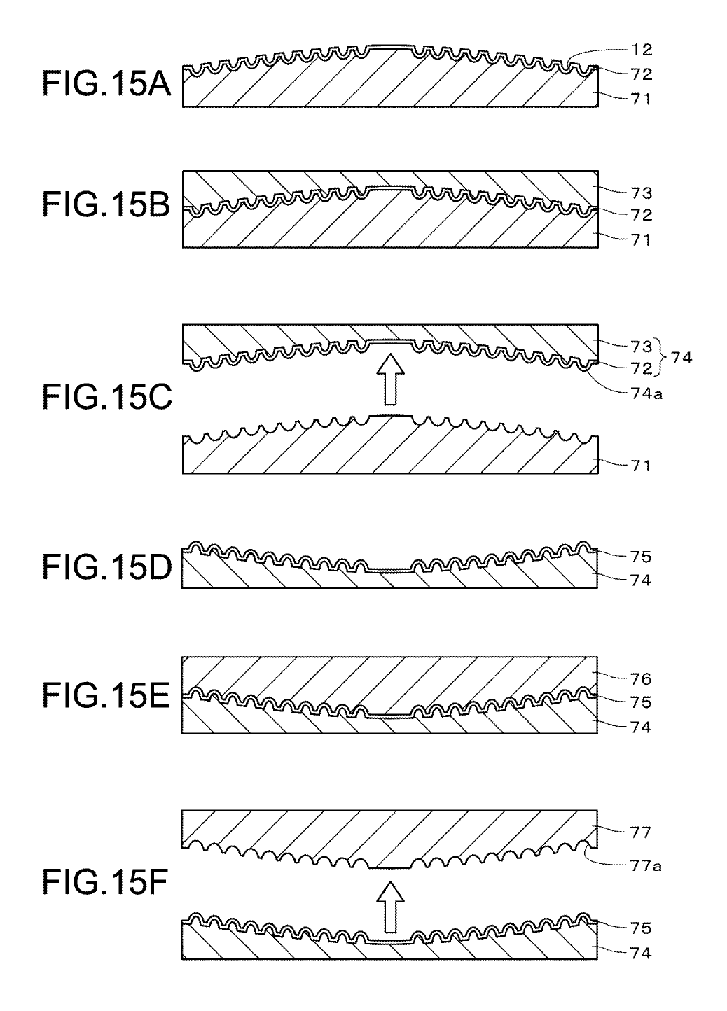

First, as shown in FIG. 15A, a conductive layer 72 is formed on the curved surface of the original plate 71 so as to follow the shape of the plurality of structures 12 by, for example, a sputtering method or electroless plating. Next, as shown in FIG. 15B, a metal layer 73 made of Ni or the like is formed on the conductive layer 72 of the original plate 71 by, for example, electroforming. Then, as shown in FIG. 15C, the metal layer 73 is separated from the original plate 71 together with the conductive layer 72. Thus, a master original plate 74 having a plurality of convex structures 74a provided on the concave curved surface thereof is obtained.

(Method of Manufacturing Mother Original Plate)

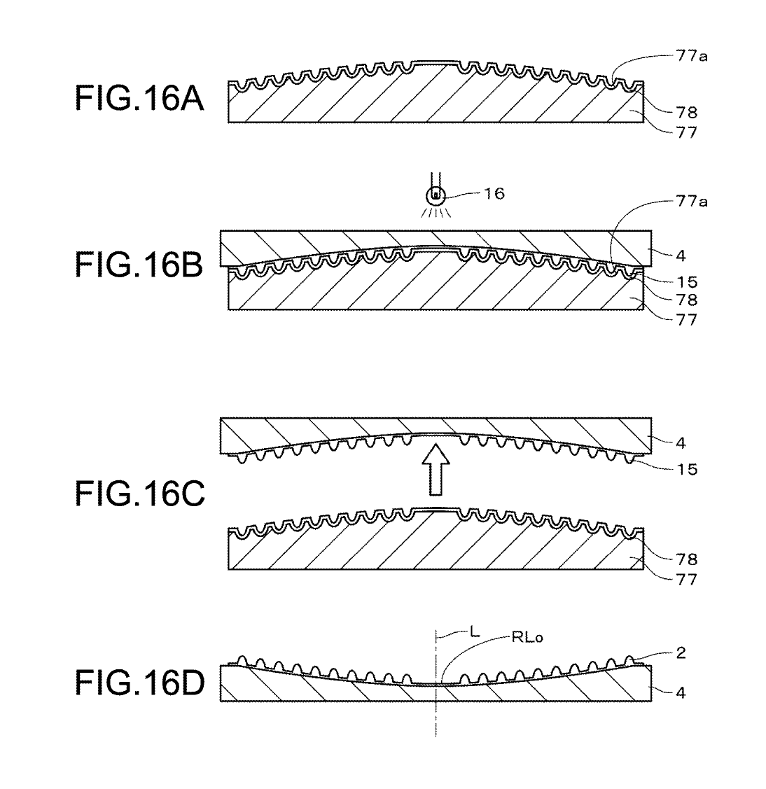

Next, as shown in FIG. 15D, a separation layer 75 is formed on the curved surface of the master original plate 74. Then, as shown in FIG. 15E, a metal layer 76 made of nickel or the like is formed on the curved surface of the master original plate 74 by, for example, an electroforming method. Next, as shown in FIG. 15F, the metal layer 76 is separated from the master original plate 74. Thus, a mother original plate 77 having a plurality of concave structures 77a provided on the convex curved surface thereof is obtained. Then, as shown in FIG. 16A, a separation layer 78 may be formed on the convex curved surface of the mother original plate 77 so as to follow the shape of the plurality of structures 77a if necessary.

(Method of Manufacturing Optical Device)

Next, as shown in FIG. 16B, the transfer material 15 is interposed between the concave curved surface of the device main body 4 and the convex curved surface (molding surface) of the mother original plate 77 and brought into intimate contact with both the curved surfaces, while an energy ray such as ultraviolet light is applied from the energy ray source 16 onto the transfer material 15. Thus, the transfer material 15 is cured. Then, as shown in FIG. 16C, the device main body 4 integrated with the cured transfer material 15 is separated from the curved surface of the mother original plate 77. Thus, as shown in FIG. 16D, the plurality of convex structures 2 are formed on the concave curved surface of the device main body 4. In the way described above, the optical device is obtained as desired.

### 3. Third Embodiment

A third embodiment will describe a method of manufacturing the optical device by injection molding.

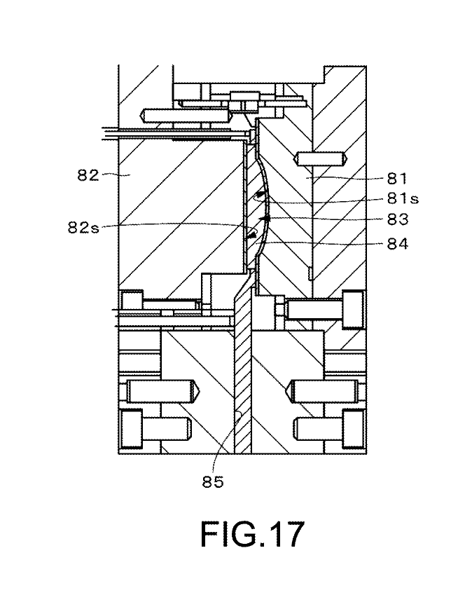

Hereinafter, a description will be given, with reference to FIG. 17, of an example of the method of manufacturing the optical device according to the third embodiment of the present technology. First, a movable die 81 is moved so as to be closer to a fixed die 82, and the movable die 81 and the fixed die 82 are butted against each other to have a cavity 83 therebetween. A molding surface 81s of the movable die 81 has the same configuration as that of the molding surface of the original plate 11 of the first embodiment. Note that instead of the molding surface 81s of the movable die 81, a molding surface 82s of the fixed die 82 may have the same configuration as that of the molding surface of the original plate 11 of the first embodiment.

Next, a melted resin material 84 is filled in the cavity 83. As the resin material, a thermoplastic resin such as an acrylic resin (PMMA), a polycarbonate resin (PC), and a cycloolefin polymer resin (COP) may be, for example, used. The resin material is heated and melted in a material supply apparatus (not shown) and supplied to the cavity 83 via a runner 85 that serves as a supply path.

Then, the melted resin material 84 filled in the cavity 83 is cooled, solidified, and clamped. Note that when the resin material 84 is clamped, the movable die 81 is moved so as to be much closer to the fixed die 82. Thus, the resin material 84 filled in the cavity 83 is pressed, whereby the fine concave and convex shape of the molding surface 81s of the movable die 81 is reliably transferred.

Next, after the resin material 84 is sufficiently cooled and solidified, the movable die 81 is moved so as to be distant from the fixed die 82 while the solidified resin material 84 is released from the movable die 81 and the fixed die 82. Through the steps described above, the optical device is obtained as desired.

### 4. Fourth Embodiment

A fourth embodiment will describe a method of manufacturing the optical device in which a fine structure pattern is transferred onto the front surface of a glass member by thermal pressure.

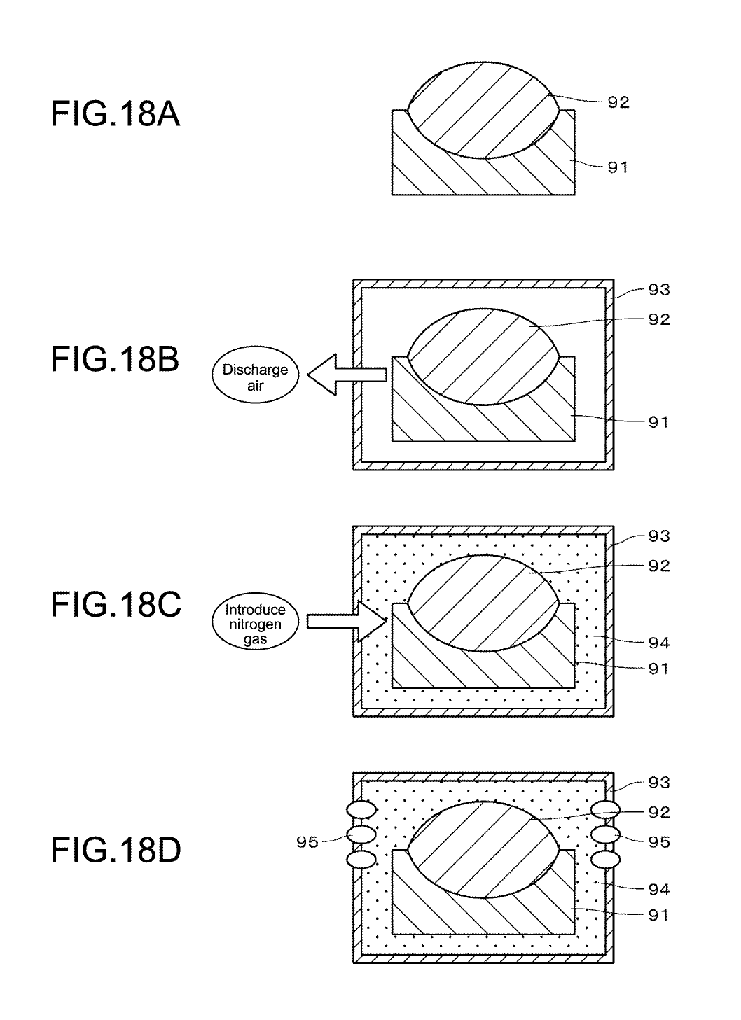

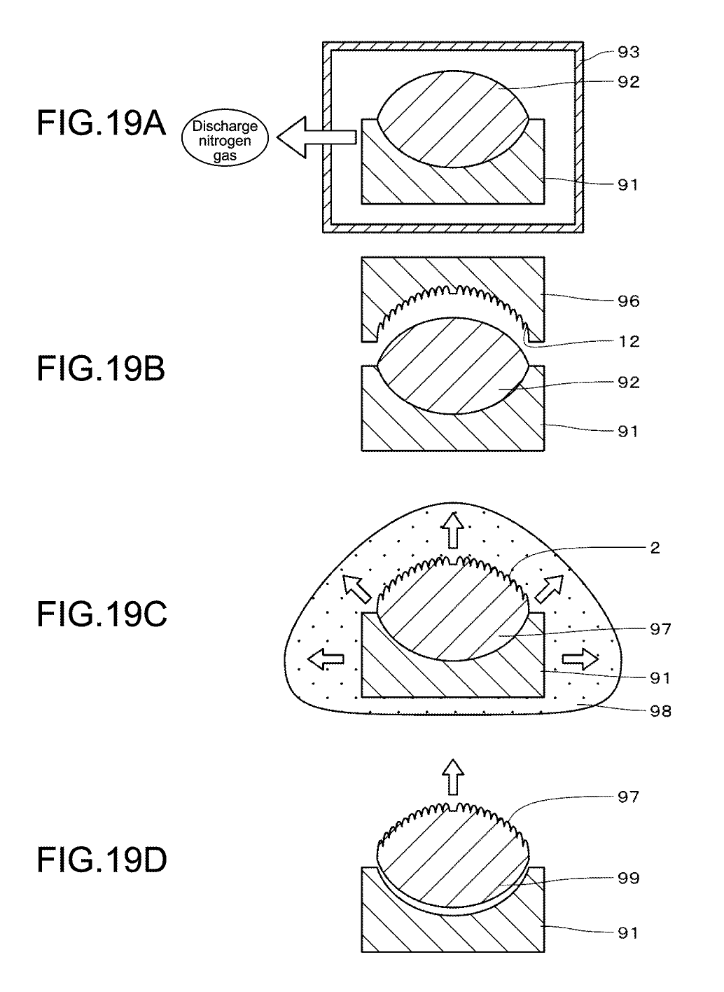

Hereinafter, a description will be given, with reference to FIGS. 18A to 18D to FIGS. 19A to 19D, of an example of the method of manufacturing the optical device according to the fourth embodiment of the present technology. First, as shown in FIG. 18A, a glass member 92 is mounted on the concave curved surface of a die 91. As the glass member 92, a low-melting glass or the like may be, for example, used. Next, as shown in FIG. 18B, a chamber 93 in which the die 91 is accommodated is evacuated. Then, as shown in FIG. 18C, nitrogen gas 94 is filled in the chamber 93. Next, as shown in FIG. 18D, the die 91 and the glass member 92 are heated to a molding temperature by infrared lamps 95.

Then, as shown in FIG. 19A, the nitrogen gas 94 in the chamber 93 is discharged to evacuate the chamber 93. Next, as shown in FIG. 19B, the glass member 92 is pressed by the molding surface of a die 96. Thus, as shown in FIG. 19C, an optical device 97 having the plurality of structures 2 on one convex curved surface thereof is formed. Note that the die 96 has the same configuration as that of the original plate 11 of the first embodiment. Then, as shown in FIG. 19C, the die 91 and the optical device 97 are simultaneously cooled by nitrogen gas 98. Next, as shown in FIG. 19D, the molded optical device 97 is taken out from the die 91.

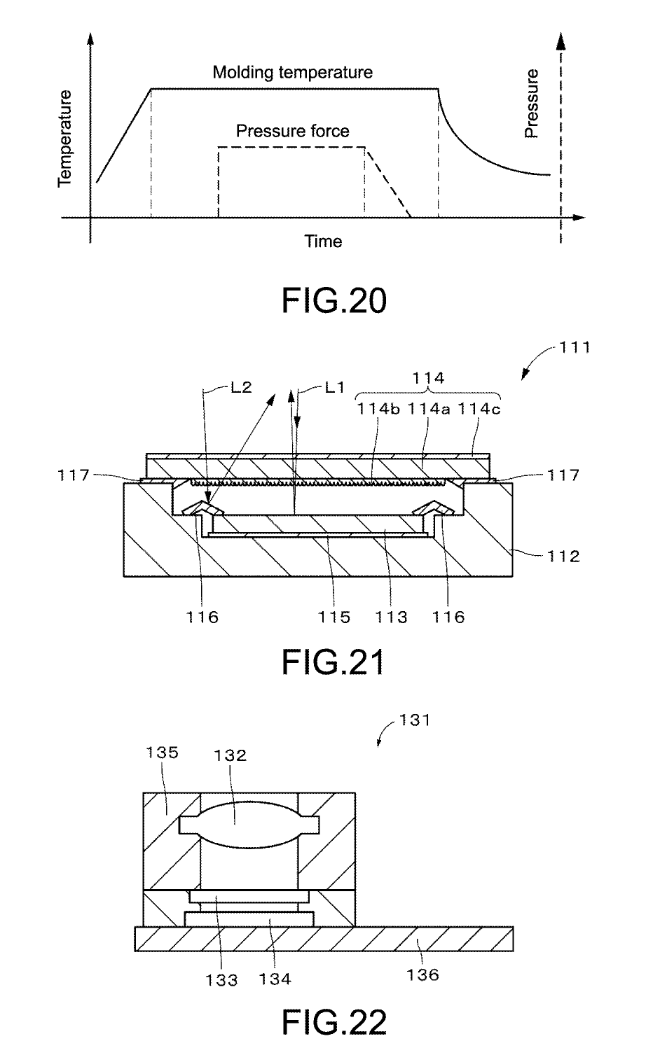

FIG. 20 is a graph showing an example of controlling a molding temperature and a pressing force in the method of manufacturing the optical device according to the fourth embodiment of the present technology. The temperature of the optical device is increased in the steps of FIGS. 18A to 18D, maintained at the molding temperature in the steps of FIGS. 19A and 19B, and decreased in the step of FIG. 19C.

### 5. Fifth Embodiment

As shown in FIG. 21, an imaging device package (hereinafter referred to as a “device package”) 111 according to a fifth embodiment of the present technology has a package 112 made of alumina or the like, an imaging device 113 accommodated in the package 112, an antireflection cover glass (cover body) 114 firmly fixed so as to cover the opening window of the package 112.

The imaging device 113 is fixed at the prescribed position of the package 112 by a die bonding agent 115.

The imaging device 113 is electrically connected to the package 112 by a wire 116. The peripheral portions of the antireflection cover glass 114 and the package 112 are bonded together by an adhesive 117 such as an epoxy-based seal resin.

As the imaging device 113, a CCD (Charge Coupled Device) imaging sensor device, a CMOS (Complementary Metal-Oxide Semiconductor) imaging sensor device, or the like may be, for example, used.

The antireflection cover glass 114 is an example of the optical device and has a cover glass main body 114a, a plurality of structures 114b, and an AR (AntiReflection) coat 114c. The plurality of structures 114b are provided on one of the principal surfaces of the cover glass main body 114a on a side opposite to the imaging device 113. The AR coat 114c is provided on the other of the principal surfaces of the cover glass main body 114a on a side on which light from a subject is incident. The plurality of structures 114b are the same as the plurality of structures 2 of the first embodiment. Note that instead of the AR coat 114c, the plurality of structures 114b may be provided on the front surface on the side on which light from a subject is incident.

The antireflection cover glass 114 may further have an optical low-pass filter and an infrared reduction filter (IR reduction filter) between the cover glass main body 114a and the AR coat 114c.

In the device package 111 according to the fifth embodiment, the plurality of structures 114b are provided on one of the principal surfaces of the cover glass main body 114a on the side opposite to the imaging device 113. Accordingly, it is possible to obtain an excellent antireflection effect not only for light reflected by the front surface of the imaging device 113 but for light reflected by the front surface of a structure such as the wire 116.

### 6. Sixth Embodiment

As shown in FIG. 22, a camera module (imaging module) 131 according to a sixth embodiment of the present technology has a lens 132, an IR reduction filter 133, an imaging device 134, a housing 135, and a circuit substrate 136. The camera module 131 is desirably applied to electronic apparatuses such as personal computers, tablet computers, and mobile phones.

The imaging device 134 is mounted at a prescribed position on the front surface of the circuit substrate 136.

The housing 135 is fixed to the front surface of the circuit substrate 136 so as to accommodate the imaging device 134. The lens 132 and the IR reduction filter 133 are accommodated in the housing 135. The lens 132 and the IR reduction filter 133 are provided in this order from a subject to the imaging device 134 with a prescribed interval therebetween. Light from a subject is condensed by the lens 132 and formed into an image on the imaging surface of the imaging device 134 via the IR reduction filter 133. The lens 132 and the IR reduction filter 133 have the plurality of structures 2 of the first embodiment on the front surfaces thereof. Here, the front surfaces represent at least one of incident surfaces on which light from a subject is incident and emission surfaces from which the light incident from the incident surfaces is emitted.

### 7. Seventh Embodiment

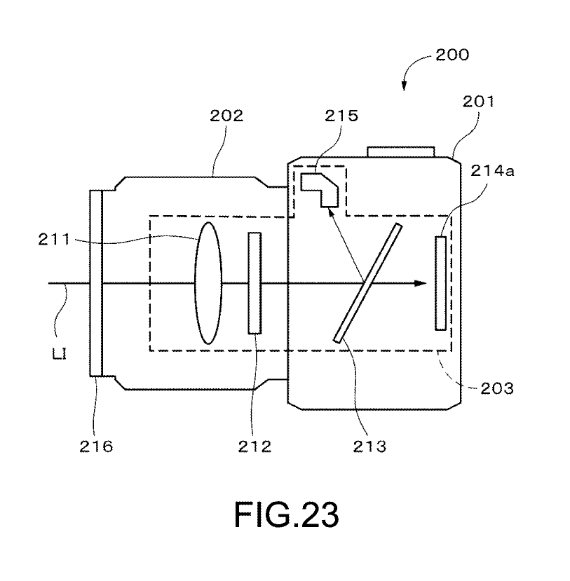

As shown in FIG. 23, an imaging apparatus 200 according to a seventh embodiment is a so-called digital camera (digital still camera) and has a housing 201, a lens barrel 202, and an imaging optical system 203 provided in the housing 201 and the lens barrel 202. The housing 201 and the lens barrel 202 may be detachable.

The imaging optical system 203 has a lens 211, a light-amount adjuster 212, a semi-transmission mirror 213, a device package 214a, and an auto focus sensor 215. The lens 211, the light-amount adjuster 212, and the semi-transmission mirror 213 are provided in this order from the tip end of the lens barrel 202 to the device package 214a. At least one type selected from a group including the lens 211, the light-amount adjuster 212, the semi-transmission mirror 213, and the device package 214a has an antireflection function. The auto focus sensor 215 is provided at a position at which light LI reflected by the semi-transmission mirror 213 is receivable. The imaging apparatus 200 may further have a filter 216 if necessary. When the imaging apparatus 200 has the filter 216, the filter 216 may have an antireflection function. Hereinafter, the respective constituents and the antireflection function will be described sequentially.

(Lens)

The lens 211 condenses the light LI from a subject toward the device package 214a.

(Light-Amount Adjuster)

The light-amount adjuster 212 is an aperture unit that adjusts a size of an aperture opening about the light axis of the imaging optical system 203. The light-amount adjuster 212 has, for example, a pair of aperture blades and an ND (Neutral Density) filter that reduces a transmission amount of light. As the driving system of the light-amount adjuster 212, a system in which the pair of aperture blades and the ND filter are driven by one actuator and a system in which the pair of aperture blades and the ND filter are driven by two separate actuators may be used. However, the driving system is not particularly limited to such systems. As the ND filter, a filter whose transmittance or density is constant or a filter whose transmittance or density changes gradually may be used. In addition, the number of the ND filters is not limited to one, but a plurality of laminated ND filters may be used.

(Semi-Transmission Mirror)

The semi-transmission mirror 213 is a mirror that causes a part of incident light to pass through and reflects the rest of the light. Specifically, the semi-transmission mirror 213 reflects a part of the light LI condensed by the lens 211 toward the auto focus sensor 215 while causing the rest of the light LI to pass through toward the device package 214a. Examples of the shape of the semi-transmission mirror 213 may include, but not particularly limited to, a sheet shape and a plate shape. Here, it is defined that a sheet includes a film.

(Device Package)

The device package 214a receives light passing through the semi-transmission mirror 213, converts the received light into an electric signal, and outputs the signal to a signal processing circuit (not shown). As the device package 214a, the device package 111 according to the fifth embodiment may be used.

(Auto Focus Sensor)

The auto focus sensor 215 receives light reflected by the semi-transmission mirror 213, converts the received light into an electric signal, and outputs the signal to a control circuit (not shown).

(Filter)

The filter 216 is provided at the tip end of the lens barrel 202 or provided in the imaging optical system 203. Note that FIG. 23 shows an example in which the filter 216 is provided at the tip end of the lens barrel 202. In this case, the filter 216 may be detachable from the tip end of the lens barrel 202.

As the filter 216, a filter generally provided at the tip end of the lens barrel 202 or provided in the imaging optical system 203 is used and not particularly limited. Examples of the filter include a polarization (PL) filter, a sharp cut (SC) filter, a color emphasizing-and-effecting filter, a neutral density (ND) filter, a light balancing (LB) filter, a color correction (CC) filter, a white balance acquisition filter, and a lens protection filter.

(Antireflection Function)

In the imaging apparatus 200, the light LI from a subject passes through the plurality of optical devices (i.e., the lens 211, the light-amount adjuster 212, the semi-transmission mirror 213, and the cover glass of the device package 214a) before reaching the imaging device in the device package 214a via the tip end of the lens barrel 202. In the following description, the optical devices through which the light LI from a subject passes before reaching the imaging device after being taken in the imaging apparatus 200 will be referred to as “transmission optical devices.” When the imaging apparatus 200 further has the filter 216, the filter 216 is also identified as one of the transmission optical devices.

At least one of the plurality of transmission optical devices has the plurality of structures 2 of the first embodiment at the front surface thereof. Here, the front surface of the transmission optical devices represents at least one of an incident surface on which the light LI from a subject is incident and an emission surface from which the light LI incident from the incident surface is emitted.

Specifically, the device package 111 according to the fifth embodiment may be, for example, used as the device package 214a. The transmission optical devices may desirably have a region RL₀, in which the plurality of structures 2 are not provided, at the central portions of the curved surfaces or the plane surfaces thereof. The region RL₀ is desirably provided on the optical axis of the imaging optical system 203.

### 8. Eighth Embodiment

The seventh embodiment described above exemplifies a case in which the present technology is applied to a digital camera (digital still camera) that serves as an imaging apparatus. However, the present technology may be applied to any other cases. An eighth embodiment of the present technology will describe an example in which the present technology is applied to a digital video camera.

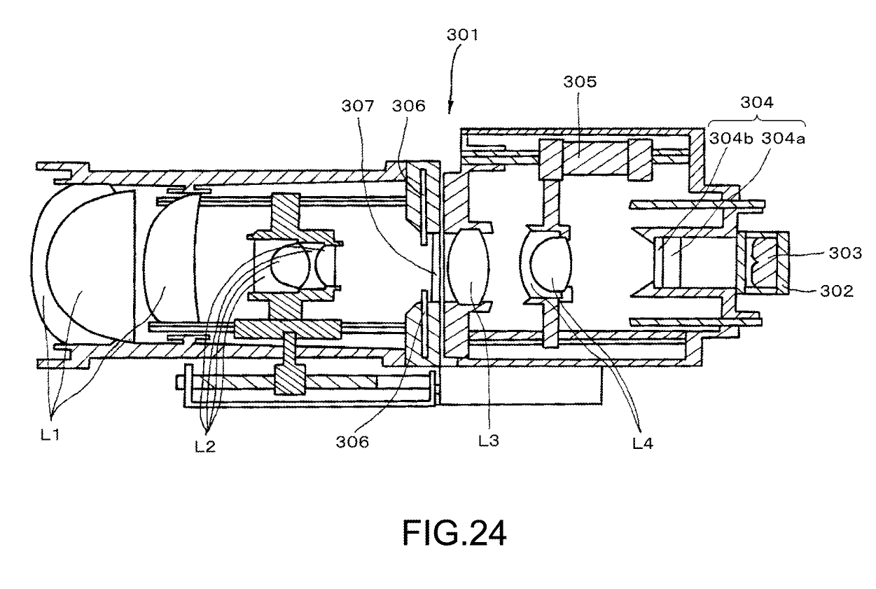

As shown in FIG. 24, an imaging apparatus 301 according to the eighth embodiment is a so-called digital video camera and has a first lens group L1, a second lens group L2, a third lens group L3, a fourth lens group L4, a device package 302, a low-pass filter 303, a filter 304, a motor 305, an iris blade 306, and an electric dimmer device 307. In the imaging apparatus 301, an imaging optical system is constituted by the first lens group L1, the second lens group L2, the third lens group L3, the fourth lens group L4, the device package 302, the low-pass filter 303, the filter 304, the iris blade 306, and the electric dimmer device 307. At least one type selected from a group including these optical devices constituting the imaging optical system has an antireflection function. An optical adjuster is constituted by the iris blade 306 and the electric dimmer device 307. Hereinafter, the respective constituents and the antireflection function will be described sequentially.

(Lens Groups)

The first lens group L1 and the third lens group L3 are fixed lenses. The second lens group L2 is a zoom lens. The fourth lens group L4 is a focus lens.

(Device Package)

The device package 302 converts incident light into an electric signal and supplies the signal to a signal processing unit (not shown). As the device package 302, the device package 111 according to the fifth embodiment may be used.

(Low-Pass Filter)

The low-pass filter 303 is provided on the front-surface side of the device package 302, i.e., on the light incident surface of the cover glass of the device package 302. The low-pass filter 303 is used to reduce a false signal (moire) generated when a striped image or the like having a pitch close to a pixel pitch is taken, and is made of, for example, artificial crystal.

The filter 304 is, for example, used to reduce the infrared region of light incident on the device package 302, prevent spectral floating in a near-infrared region (630 nm to 700 nm), and make light intensity in a visible region (400 nm to 700 nm) even. The filter 304 is constituted by, for example, an infrared reduction filter (hereinafter referred to as an “IR reduction filter”) 304a and an IR reduction coat layer 304b, i.e., an IR reduction coat laminated on the IR reduction filter 304a. Here, the IR reduction coat layer 304b is formed on, for example, at least one of the surface of the IR reduction filter 304a on the side of a subject and the surface of the IR reduction filter 304a on the side of the device package 302. FIG. 24 shows an example in which the IR reduction coat layer 304b is formed on the surface of the IR reduction filter 304a on the side of a subject.

The motor 305 moves the fourth lens group L4 based on a control signal supplied from a control unit (not shown). The iris blade 306 is used to adjust an amount of light incident on the device package 302 and driven by a motor (not shown).

The electric dimmer device 307 is used to adjust the amount of light incident on the device package 302. The electric dimmer device 307 is an electric dimmer device made of a liquid crystal containing at least a dye-based pigment, e.g., an electric dimmer device made of a dichroic GH liquid crystal.

(Antireflection Function)

In the imaging apparatus 301, light from a subject passes through the plurality of optical devices (the first lens group L1, the second lens group L2, the electric dimmer device 307, the third lens group L3, the fourth lens group L4, the filter 304, and the cover glass with the low-pass filter 303) before reaching the imaging device in the device package 302. In the following description, the optical devices through which light LI from a subject passes before reaching the imaging device will be referred to as “transmission optical devices.” At least one of the plurality of transmission optical devices has the plurality of structures 2 of the first embodiment on the front surface thereof. Specifically, the device package 111 according to the fifth embodiment may be, for example, used as the device package 302. The transmission optical devices may desirably have a region RL₀, in which the plurality of structures 2 are not provided, at the central portions of the curved surfaces or the plane surfaces thereof. The region RL₀ is desirably provided on the optical axis of the imaging optical system.

### 9. Ninth Embodiment

A ninth embodiment will describe an example of an electronic apparatus having the camera module 131 according to the sixth embodiment.

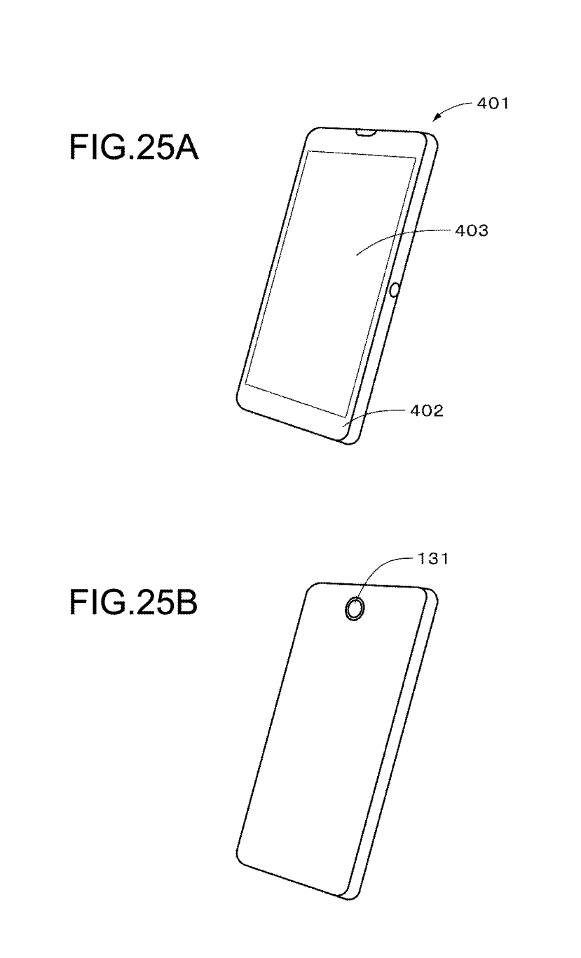

As shown in FIGS. 25A and 25B, a mobile phone 401 as an example of the electronic apparatus is a so-called smart phone and has a housing 402, a display device 403 with a touch panel, and the camera module 131, the display device 403 and the camera module 131 being accommodated in the housing 402. The display device 403 with the touch panel is provided on the front-surface side of the mobile phone 401, and the camera module 131 is provided on the back-surface side thereof. Here, the display device 403 with the touch panel may have the plurality of structures 2 of the first embodiment on the input operation surface thereof.

### EXAMPLES

Hereinafter, the present technology will be specifically described based on Examples but is not limited only to the Examples.

### Example 1

### Resist Deposition Process

First, a glass original plate having a convex aspherical surface was prepared. Next, an inorganic resist layer was evenly formed on the aspherical surface of the glass original plate.

(Exposure Process)

Then, the glass original plate was rotated and laser light was intermittently applied while being moved from the center to the peripheral direction (radius direction) of the aspherical surface of the glass original plate, whereby the inorganic resist layer formed on the aspherical surface of the glass original plate was exposed. On this occasion, a laser optical system was controlled such that the laser light was kept perpendicularly incident on the aspherical surface of the glass original plate. In addition, the laser optical system was controlled such that a plurality of latent images were spirally formed as a whole and that a substantially hexagonal lattice pattern was locally formed when the aspherical surface of the glass original plate was seen in the central-axis direction thereof. Note that the laser light was applied at a feeding pitch of 200 nm in the radius direction of the glass original plate and applied at a feeding pitch of 230 nm in the rotation direction thereof.

(Development Process)

Next, for example, a developing solution was dropped onto the inorganic resist layer while the glass original plate was rotated, whereby the inorganic resist layer was developed in a direction perpendicular to the aspherical surface of the glass original plate. Thus, a plurality of opening portions corresponding to the latent images were formed on the inorganic resist layer.

(Etching Process)

Then, the aspherical surface of the glass original plate was etched using the inorganic resist layer having the plurality of opening portions as a mask. On this occasion, the etching process was controlled such that glass original plate was etched in the central-axis direction thereof. Thus, a plurality of structures were formed on the aspherical surface of the glass original plate. Next, the inorganic resist layer remaining on the aspherical surface of the glass original plate was removed by ashing.

(Transfer Process)

Then, an ultraviolet curable resin composition was interposed between the concave aspherical surface of a plano-concave lens and the convex aspherical surface (molding surface) of the glass original plate, brought into intimate contact with both the aspherical surfaces, and cured by the application of ultraviolet light. Next, the plano-concave lens integrated with the cured ultraviolet curable resin was separated from the aspherical surface of the glass original plate. Thus, a plurality of structures were spirally formed on the concave aspherical surface of the plano-concave lens. Note that the column pitch of the structures between the adjacent portions of the spiral was 200 nm and the pitch of the structures in the peripheral direction of the spiral was 230 nm. In addition, the diameter of the bottom surfaces of the structures was 200 nm, and the height of the structures was 200 nm. In the way described above, an antireflection plano-concave lens was obtained as desired.

### Comparative Example 1

A four-layer AR coat was formed on the concave aspherical surface of a plano-concave lens, whereby an antireflection plano-concave lens was obtained.

(Evaluation of Reflection Spectrums)

Each of the reflection spectrums of the antireflection plano-concave lenses of Example 1 and Comparative Example 1 was evaluated as follows. First, a black tape was adhered to the plane side of the antireflection plano-concave lens.

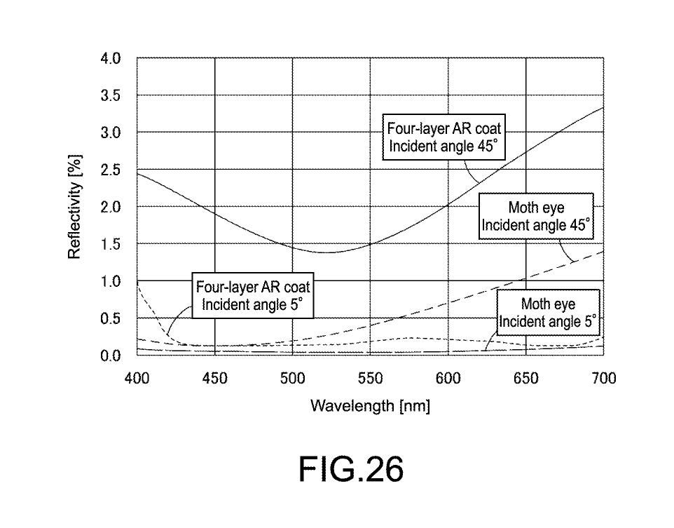

Next, light was incident at an incident angle of 5° or 45° on a concave aspherical surface on a side opposite to the side where the black tape is adhered to evaluate the reflection spectrum (wavelength band: 400 nm to 700 nm). FIG. 26 shows the results. Note that the incident angle is an angle based on the normal line of the concave aspherical surface of the plano-concave lens.

FIG. 26 shows the following aspects.

Reflection Spectrum at Incident Angle of 5°

As for Example 1 in which the plurality of structures are provided on the concave aspherical surface, the reflection spectrum hardly depends on wavelengths and is almost flat. On the other hand, as for Comparative Example 1 in which the four-layer AR coat is provided on the concave aspherical surface, the reflection spectrum is almost flat but tends to slightly increase near a wavelength of 400 nm.

Reflection Spectrum at Incident Angle of 45°

As for Example 1 in which the plurality of structures are provided on the concave aspherical surface, it appears that the reflection spectrum tends to increase in a range of 500 nm to 700 nm. On the other hand, as for Comparative Example 1 in which the four-layer AR coat is provided on the concave aspherical surface, it appears that the reflection spectrum tends to increase in a range of 400 nm to 700 nm. The increasing degree of the reflection spectrum of Comparative Example 1 is greater than that of Example 1.

The embodiments of the present technology are described above. However, the present technology is not limited to the embodiments described above but may be modified in various ways based on the technical ideas of the present technology.

For example, the configurations, the methods, the processes, the shapes, the materials, the numerical values, or the like of the embodiments described above are only for illustration. If necessary, different configurations, methods, processes, shapes, materials, numerical values, or the like may be used.

In addition, the configurations, the methods, the processes, the shapes, the materials, the numerical values, or the like of the embodiments described above may be combined together so as not to depart from the spirit of the present technology.

In addition, the present technology may employ the following configurations.

(1-1) An optical device, including:

a curved surface; and

a plurality of structures spirally provided on the curved surface at an interval of less than or equal to a wavelength of light for which reflection is to be reduced,
each of the plurality of structures including one of a convex portion protruding in a light-axis direction and a concave portion recessed in the light-axis direction,
the curved surface having a region, in which the plurality of structures are not provided, at a center thereof.

(1-2) The optical device according to (1-1), in which

a spiral formed by the plurality of structures and the center of the curved surface correspond to or substantially correspond to each other.

(1-3) The optical device according to (1-1) or (1-2), in which

the curved surface has a shape symmetrical with respect to a light axis, and

the center of the curved surface includes one of an apex portion and a bottom portion of the curved surface.

(1-4) The optical device according to any one of (1-1) to (1-3), in which

the curved surface includes one of a spherical surface and an aspherical surface.

(1-5) The optical device according to any one of (1-1) to (1-4), in which

the curved surface includes one of a convex shape and a concave shape.

(1-6) The optical device according to any one of (1-1) to (1-5), in which

the plurality of structures contain an ultraviolet curable resin.

(1-7) The optical device according to any one of (1-1) to (1-6), in which

the light includes visible light.

(1-8) The optical device according to any one of (1-1) to (1-7), in which

the plurality of structures are arranged in a lattice pattern on the curved surface.

(1-9) An original plate, including:

a curved surface; and

a plurality of structures spirally provided on the curved surface at an interval of less than or equal to a wavelength of light for which reflection is to be reduced,
each of the plurality of structures including one of a convex portion protruding in a central-axis direction of the curved surface and a concave portion recessed in the central-axis direction thereof,
the curved surface having a region, in which the plurality of structures are not provided, at a center thereof.

(1-10) An imaging apparatus, including:

the optical device according to any one of (1-1) to (1-9).

(1-11) The imaging apparatus according to (1-10), further including:

an optical system having the optical device, in which

the region is provided on a light axis of the optical system.

(1-12) A method of manufacturing an original plate, including:

perpendicularly applying light onto a curved surface of the original plate to form spiral exposure portions on a resist provided on the curved surface of the original plate at an interval of less than or equal to a wavelength of light for which reflection is to be reduced;

developing a resist layer having the plurality of exposure portions to form a resist pattern; and

etching the original plate in a central-axis direction of the curved surface using the resist pattern as a mask to form a plurality of structures on the curved surface.

Moreover, the present technology may employ the following configurations.

(2-1) A method of manufacturing an original plate, including:

exposing a resist layer formed on one of a curved surface and a plane surface of the original plate in a prescribed pattern;

developing the resist layer to form a mask having a plurality of opening portions; and

etching one of the curved surface and the plane surface of the original plate in a central-axis direction of the original plate based on a difference in an etching rate between the plurality of opening portions and a remaining portion of the mask to form a plurality of structures on one of the curved surface and the plane surface of the original plate.

(2-2) The method of manufacturing the original plate according to (2-1), in which

the exposure is controlled such that an incident direction of light corresponds to a normal-line direction of one of the curved surface and the plane surface when the original plate is rotated about a central axis thereof and a focal position of the light for use in the exposure is moved from a center to a peripheral direction of the original plate.

(2-3) The method of manufacturing the original plate according to (2-1) or (2-2), in which,

in the exposure, an application time, an application energy amount, and an application interval of the light for use in the exposure are numerically controlled.

(2-4) The method of manufacturing the original plate according to any one of (2-1) to (2-3), in which,

in the exposure, the application time, the application energy amount, and the application interval are changed for each exposure point to appropriately adjust a position, a size, a shape, a depth, and a slant-surface shape of the plurality of structures obtained by the etching.

(2-5) The method of manufacturing the original plate according to any one of (2-1) to (2-4), further including

manufacturing a duplicate original plate based on the original plate.

(2-6) The method of manufacturing the original plate according to (2-5), in which

the duplicate original plate is manufactured in such a way that a conductive layer is deposited on one of the curved surface and the plane surface of the original plate by one of sputtering and deposition and then a metal layer is formed on the conductive layer by electroforming.

(2-7) The method of manufacturing the original plate according to any one of (2-1) to (2-6), in which

the curved surface of the original plate includes a spherical surface.

(2-8) The method of manufacturing the original plate according to any one of (2-1) to (2-7), in which

the plurality of structures are provided at an interval of less than or equal to a wavelength of light for which reflection is to be reduced.

(2-9) The method of manufacturing the original plate according to any one of (2-1) to (2-8), in which

the structures include moth-eye structures.

(2-10) The method of manufacturing the original plate according to any one of (2-1) to (2-9), in which

the resist layer contains an incomplete oxide of transition metal.

(2-11) A method of manufacturing an optical device, including:

exposing a resist layer formed on one of a curved surface and a plane surface of the original plate in a prescribed pattern;

developing the resist layer to form a mask having a plurality of opening portions;

etching one of the curved surface and the plane surface of the original plate in a central-axis direction of the original plate based on a difference in an etching rate between the plurality of opening portions and a remaining portion of the mask to form a plurality of structures on one of the curved surface and the plane surface of the original plate; and

forming the optical device having a plurality of structures using one of the original plate and a duplicate original plate of the original plate.

(2-12) The method of manufacturing the optical device according to (2-11), in which

the optical device having the plurality of structures is formed in such a way that a shape-transfer is performed on an ultraviolet curable resin using one of the original plate and the duplicate original plate.

(2-13) The method of manufacturing the optical device according to (2-11) or (2-12), in which

the optical device includes a lens having an aspherical shape, and

the plurality of structures are formed on the aspherical surface.

(2-14) An imaging device package, including:

an imaging device; and

a package accommodating the imaging device,

the package having a light transmission unit in which a plurality of structures are spirally provided at an interval of less than or equal to a wavelength of light for which reflection is to be reduced.

(2-15) The imaging device package according to (2-14), in which

the light transmission unit includes a glass plate.

(2-16) The imaging device package according to (2-14) or (2-15), in which

a spiral formed by the plurality of structures has a region, in which the plurality of structures are not provided, at a central portion thereof.

(2-17) The imaging device package according to any one of (2-14) to (2-16), in which

the plurality of structures are provided on one surface of the glass plate, and a multi-layer antireflection film is provided on the other surface thereof.

(2-18) The imaging device package according to (2-17), in which

the surface on which the plurality of structures are provided opposes the imaging device.

What is claimed is:

1. An optical device, comprising:
a curved surface; and
a plurality of structures spirally provided on the curved surface at an interval of less than or equal to a wavelength of light for which reflection is to be reduced,
each of the plurality of structures including one of a convex portion protruding in a light-axis direction and a concave portion recessed in the light-axis direction,
the curved surface having a region, in which the plurality of structures are not provided, at a center thereof.

2. The optical device according to claim 1, wherein
a spiral formed by the plurality of structures and the center of the curved surface correspond to or substantially correspond to each other.

3. The optical device according to claim 1, wherein
the curved surface has a shape symmetrical with respect to a light axis, and
the center of the curved surface includes one of an apex portion and a bottom portion of the curved surface.

4. The optical device according to claim 1, wherein
the curved surface includes one of a spherical surface and an aspherical surface.

5. The optical device according to claim 1, wherein
the curved surface includes one of a convex shape and a concave shape.

6. The optical device according to claim 1, wherein
the plurality of structures contain an ultraviolet curable resin.

7. The optical device according to claim 1, wherein
the light includes visible light.

8. The optical device according to claim 1, wherein
the plurality of structures are arranged in a lattice pattern on the curved surface.

9. An original plate, comprising:
a curved surface; and
a plurality of structures spirally provided on the curved surface at an interval of less than or equal to a wavelength of light for which reflection is to be reduced,
each of the plurality of structures including one of a convex portion protruding in a central-axis direction of the curved surface and a concave portion recessed in the central-axis direction thereof,
the curved surface having a region, in which the plurality of structures are not provided, at a center thereof.

10. An imaging apparatus, comprising:
an optical device having
a curved surface and
a plurality of structures spirally provided on the curved surface at an interval of less than or equal to a wavelength of light for which reflection is to be reduced,
each of the plurality of structures including one of a convex portion protruding in a light-axis direction of the optical device and a concave portion recessed in the light-axis direction thereof,
the curved surface having a region, in which the plurality of structures are not provided, at a center thereof.

11. The imaging apparatus according to claim 10, further comprising:
an optical system having the optical device, wherein
the region is provided on a light axis of the optical system.

12. A method of manufacturing an original plate, comprising:
perpendicularly applying light onto a curved surface of the original plate to form spiral exposure portions on a resist provided on the curved surface of the original plate at an interval of less than or equal to a wavelength of light for which reflection is to be reduced;
developing a resist layer having the plurality of exposure portions to form a resist pattern; and
etching the original plate in a central-axis direction of the curved surface using the resist pattern as a mask to form a plurality of structures on the curved surface.
